(19) United States
(12) Patent Application Publication
(10) Pub. No.: US 2025/0045491 A1
(43) Pub. Date: Feb. 6, 2025

(54) SIMULATION SCENARIOS IN VEHICLE SAFETY TESTING

(71) Applicant: Pony.ai, Inc., Fremont, CA (US)

(72) Inventor: Andreas RESCHKA, Foster City, CA (US)

(21) Appl. No.: 18/365,205

(22) Filed: Aug. 3, 2023

(51) Int. Cl. G06F 30/27; G06N 5/046

(52) U.S. Cl. CPC G06F 30/27; G06N 5/046

(57) ABSTRACT

A system includes one or more processors that obtain raw data regarding one or more events of a vehicle. The system infers, within the raw data, an indication of a vehicle, vehicle attributes, an environment, and environmental attributes according to an ontological framework. The ontological framework defines linkages among the vehicle and the vehicle attributes, and relationships among the vehicle and other objects within the environment. The system transforms the raw data into a seed scenario according to the ontological framework. The seed scenario includes a file, and the seed scenario includes a description or a depiction of the vehicle, the vehicle attributes, the environment, and the environmental attributes. The system generates one or more additional scenarios by modifying the seed scenario. The modification of the seed scenario is based on modifications to the environmental attributes, the vehicle attributes, and navigation attributes.

### BACKGROUND

The meteoric rise in deployment of autonomous or semi-autonomous vehicles has been a catalyst that has spurred efforts to improve their safety. By 2040, an anticipated 75 percent of vehicles will be autonomous or semi-autonomous, according to the Institute of Electrical and Electronics Engineers (IEEE). According to current estimates from 2020 or 2021, approximately 9.1 autonomous or semi-autonomous vehicle crashes occur per million miles driven. Extensive testing is conducted on autonomous and semi-autonomous vehicles to verify their safety. One mode of such testing involves simulations.

Simulations of driving scenarios encompass controlled, reproduced situations that mimic reality with identical or similar stimuli and responses, which may otherwise be expensive, dangerous, or unrepeatable in reality. These simulations uncover potentially unsafe driving situations and measures to eliminate or reduce danger in these situations. However, generation of realistic and relevant simulations remains a bottleneck, thereby hampering autonomous and semi-autonomous vehicle development.

### SUMMARY

Described herein, in some examples, is a system that includes one or more processors that obtain raw data regarding one or more events of a vehicle (e.g., an ego vehicle). The system may include one or more processors; and a memory storing instructions that, when executed by the one or more processors, cause the system to perform certain operations. The operations may include obtaining raw data associated with one or more events of a vehicle; inferring, within the raw data, an attribute of the vehicle according to an ontological framework, wherein the ontological framework defines at least one relationship associated with the vehicle; transforming the raw data into a seed scenario according to the ontological framework, wherein the seed scenario comprises at least one file, and the seed scenario comprises a description or a depiction of the vehicle; and generating one or more additional scenarios based on one or more modifications to the seed scenario.

In some examples, the operations may include obtaining raw data regarding one or more events of a vehicle, inferring, within the raw data, an indication of a vehicle, vehicle attributes, an environment, and environmental attributes according to an ontological framework, wherein the ontological framework defines linkages or relationships among the vehicle and the vehicle attributes, and relationships among the vehicle and other objects within the environment; transforming the raw data into a seed scenario according to the ontological framework, wherein the seed scenario comprises a file, and the seed scenario comprises a description or a depiction of the vehicle, the vehicle attributes, the environment, and the environmental attributes; and generating one or more additional scenarios by modifying the seed scenario, wherein the modification of the seed scenario is based on modifications to the environmental attributes, the vehicle attributes, and navigation attributes.

In some examples, the obtaining of the raw data and the transforming of the raw data are performed in association with a large language model (LLM).

In some examples, the LLM is trained iteratively, based on a first training dataset that comprises compiled examples of correctly generated seed scenarios and previously known or obtained incorrectly generated seed scenarios before the transforming of the raw data into the seed scenario, and a second training dataset that comprises incorrectly generated scenarios during the transforming of the raw data.

In some examples, the iterative training comprises training the LLM over two stages, wherein a first stage is based on the first training dataset prior to the transforming of the raw data into the seed scenario and a second stage is based on the second training dataset following the transforming of the raw data into the seed scenario.

In some examples, the obtaining of the raw data comprises receiving any updates of new raw data from an external data source via an applications programming interface (API); and generating a queue to process the any updates.

In some examples, the raw data comprises structured data and unstructured data, and the transforming of the raw data comprises recognizing one or more additional attributes of the vehicle or of the other objects from the unstructured data that are absent or undetected from the structured data and integrating the one or more additional attributes into the seed scenario.

In some examples, the obtaining of the raw data comprises obtaining the raw data from different data sources, and the transforming of the raw data comprises resolving any discrepancies within the different data sources.

In some examples, the raw data comprises textual data and media data, and the transforming of the raw data comprises recognizing one or more additional attributes of the vehicle or of the other objects from the media data that are absent or undetected from the textual data and integrating the one or more additional attributes into the seed scenario.

In some examples, the one or more events comprise an accident or a disengagement.

In some examples, the instructions further cause the system to perform: implementing a testing simulation based on the seed scenario and the one or more additional scenarios, wherein the testing simulation comprises executing of a test driving operation involving a test vehicle based on the seed scenario and monitoring one or more test vehicle attributes of the test vehicle.

Various embodiments of the present disclosure provide a method implemented by a system as described above.

These and other features of the apparatuses, systems, methods, and non-transitory computer readable media disclosed herein, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for purposes of illustration and description only and are not intended as a definition of the limits of the invention.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the invention are utilized, and the accompanying drawings of which:

FIG. 1 illustrates an example implementation of a computing system that automatically generates seed scenarios from a corpus of data, for example, regarding a vehicle and an event.

FIG. 2 illustrates an implementation of a computing system that obtains or ingests raw data, processes the raw data, and generates a seed scenario. The seed scenario in FIG. 2 illustrates information of participants and their characteristics or behaviors.

FIG. 3 illustrates an implementation of a computing system that obtains or ingests raw data, processes the raw data, and generates a seed scenario. The seed scenario in FIG. 3 illustrates information of environmental characteristics.

FIG. 4 illustrates an implementation of a computing system that supplements the raw data with other data from different sources to generate a seed scenario. The seed scenario in FIG. 4 illustrates information of participants and their characteristics or behaviors.

FIG. 5 illustrates an implementation of a computing system that supplements the raw data with other data from different sources to generate a seed scenario. The seed scenario in FIG. 5 illustrates information of environmental characteristics.

FIG. 6 illustrates an implementation of a computing system that supplements the raw data with other media to generate a seed scenario. The seed scenario in FIG. 6 illustrates information of participants and their characteristics or behaviors.

FIG. 7 illustrates an implementation of a computing system that supplements the raw data with other media to generate a seed scenario. The seed scenario in FIG. 7 illustrates information of environmental characteristics.

FIG. 8 illustrates an implementation of a computing system that supplements the raw data with image data, such as from an interior of a vehicle (e.g., an ego vehicle), to generate a seed scenario. The image data may illustrate a dynamic or changing aspect of a vehicle during an event, such as an accident.

FIG. 9 illustrates an implementation of a computing system that supplements the raw data with image data, such as from an interior and an exterior of a vehicle (e.g., an ego vehicle), to generate a seed scenario.

FIG. 10 illustrates an implementation of a computing system that supplements the raw data with an image or video exterior to a vehicle (e.g., an ego vehicle) that shows a representation of an interaction between the vehicle and an other agent, to generate a seed scenario.

FIG. 11 illustrates an implementation of a computing system that supplements the raw data with an image or video exterior to a vehicle that shows environmental characteristics in relation to one or more participants of an event, to generate a seed scenario.

FIG. 12 illustrates an implementation of a computing system that supplements the raw data with image data, such as from an interior of a vehicle (e.g., an ego vehicle), to generate a seed scenario. The image data may illustrate a relatively static aspect of a vehicle during an event, such as an accident.

FIG. 13 illustrates an implementation of a computing system that modifies the raw data, upon detecting an inaccuracy.

FIG. 14 illustrates an implementation of a computing system that resolves an inconsistency, to generate a seed scenario. The seed scenario in FIG. 6 illustrates information of participants and their characteristics or behaviors.

FIG. 15 illustrates an implementation of a computing system that resolves an inconsistency, to generate a seed scenario. The seed scenario in FIG. 15 illustrates information of environmental characteristics.

FIG. 16 illustrates an implementation of a computing system that expands the seed scenarios to generate additional scenarios.

FIGS. 17-18 illustrate example implementations of training of machine learning components to generate seed scenarios and additional scenarios, respectively.

FIG. 19 illustrates an example implementation of downstream actions or processes.

FIG. 20 illustrates a flowchart which summarizes an exemplary process to generating seed scenarios and additional scenarios.

FIG. 21 illustrates a block diagram of a computer system upon which any of the embodiments described herein may be implemented.

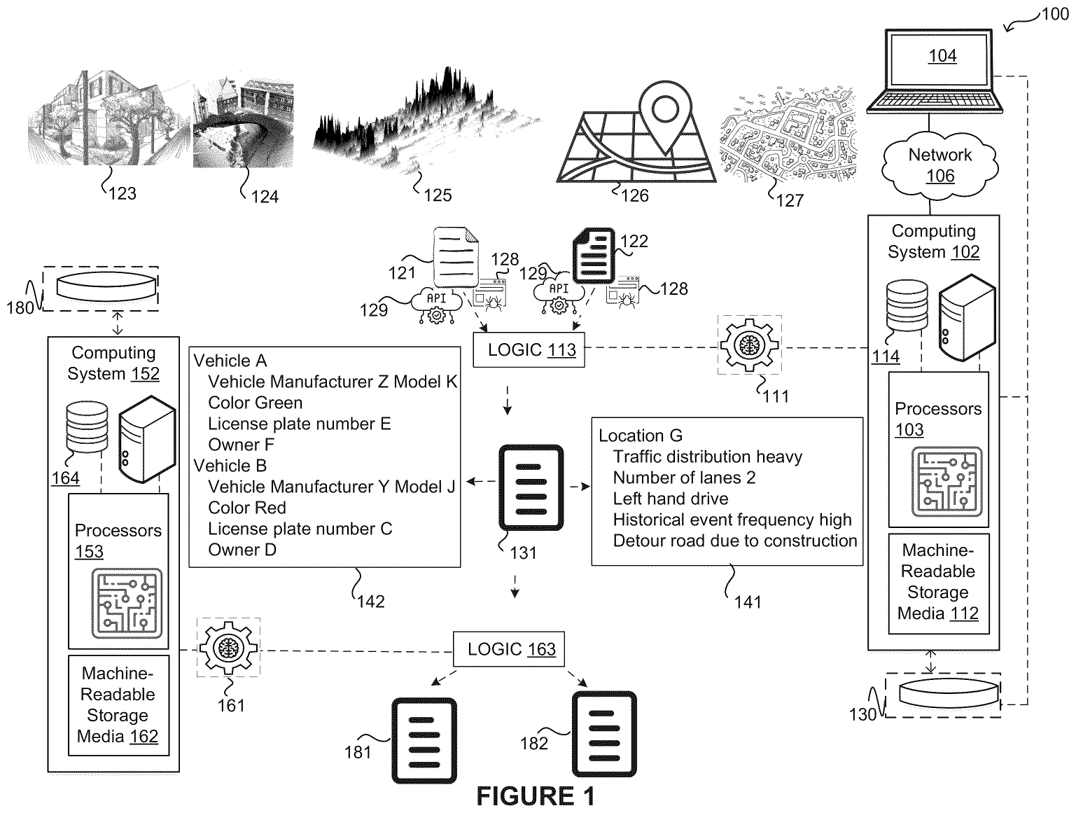

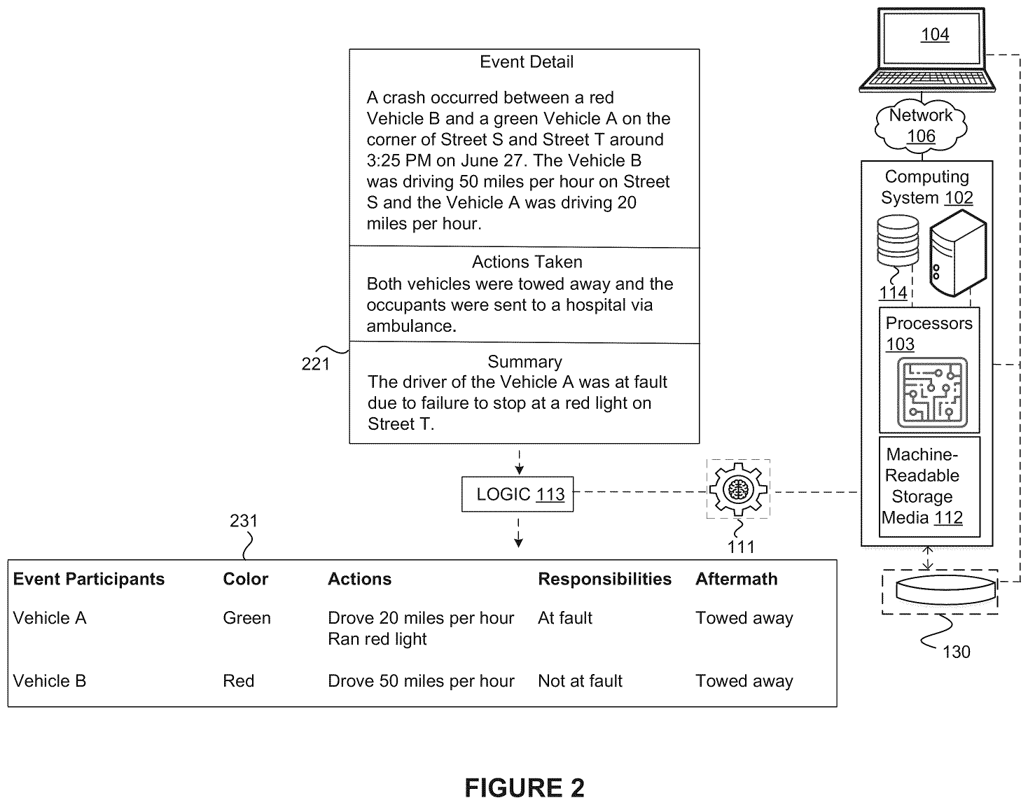

In some examples, principles from different FIGURES may apply to, and/or be combined with other FIGURES as suitable. For example, the principles illustrated in FIG. 1 may be applied to and/or combined with principles from any of FIGS. 2-21, and vice versa.

### DETAILED DESCRIPTION

In order to improve accuracy and effectiveness of testing scenarios for autonomous and semi-autonomous vehicles, a computing system, which may include or be associated with machine learning components such as Large Language Model (LLM), may generate testing scenarios based on reports, logs, and/or other data from external databases. The testing scenarios may encompass safety-critical situations in real-world driving environments. These testing scenarios may be manifested in a text format, and may encompass navigation characteristics such as speed, acceleration, following distance, yielding behavior, braking force, direction of travel, and interaction measurements such as post-encroachment time, time-to-collision, safe time headway, environmental characteristics such as road profile, road geometry, road signs, road markings, any barriers (e.g., safety barriers on a side of a road), traffic density and/or distribution, turn signals or signals from other vehicles or pedestrians, textures and colors of surround static or moving objects, lighting, shadows, angle of sunlight with respect to an occupant in a vehicle, scent (e.g., burning), and vehicle or entity/agent (hereinafter “entity”) characteristics, such as a vehicle involved in an accident or incident and/or other entities such as other vehicles (e.g., bicycles, motorcycles, and/or pedestrians), characteristics specific to a vehicle such as airbag deployment attributes, degree or extent of windshield transparency and/or tint, and/or emotions of one or more vehicle occupants. These testing scenarios may be, or represent, base scenarios or seed scenarios from which additional testing scenarios are generated. Algorithms, which may be implemented or executed by the computing system, the machine learning components, a different computing system, and/or different machine learning components, may further extend or expand the base scenarios across other locations having at least a threshold degree of similarity to that of a base scenario. Additionally or alternatively, the algorithms may further extend or expand the base scenarios by relaxing or modifying certain parameters, characteristics, attributes, and/or ranges, such as changes in navigational characteristics, changes in vehicle or other entity characteristics and/or changes in environmental characteristics. These environmental changes may include a change in a side of traffic that a vehicle is regulated to drive on, a change in an environmental condition such as lighting or visibility, a change in a weather condition such as a level of precipitation, a temperature, smog level, air quality index (AQI), a change in an amount of neighboring traffic and/or a distribution of neighboring traffic, a change in road signs such as a change in speed limits, a change in road objects such as traffic lights, a change in a sunlight angle, a change in an extent of windshield transparency or tint, a change in airbag deployment attributes, a change in a height, density, and/or a distribution of shrubbery, a change in a road surface material, one or more properties such as coefficient of friction, surface roughness, smoothness, tire-pavement noise, texture, and/or a distribution or density of obstacles such as rocks or boulders. Meanwhile, changes in walking speed, and/or walking cadence of pedestrians, behaviors of entities such as walking speed, and/or walking cadence of pedestrians and yielding behaviors, distributions of yielding behaviors, motion trajectories or motion models. Changes in vehicle characteristics may further include changes in turn signals, changes in a side that a steering wheel is disposed, and/or changes in vehicle sensors, changes in vehicle interaction with a road such as a tire-road friction coefficient, and changes in vehicle inertial parameters such as a sprung mass, yaw moment of inertia, and position of a center of gravity.

In some examples, a number and/or an extent of the additional testing scenarios generated may be based on a size, a granularity, a number, and/or a confidence level or estimated or predicted degree of accuracy or reliability of seed scenarios. For example, a larger a number of seed scenarios, a lower a number of the additional testing scenarios. In another example, if a seed scenario is estimated to be less accurate or reliable, then a lower number of additional testing scenarios may be generated. Feedback regarding the seed scenarios and/or the additional testing scenarios may be transmitted to a corresponding computing system (e.g., the computing system) and/or the corresponding machine learning components to revise the algorithms, feature weights, and/or computer code (e.g., which may include parameters, expressions, protocols, evaluations, conditions, arguments, and/or functions). This feedback may be incorporated into future generation of seed scenarios and/or additional scenarios.

In such a manner, comprehensive realistic and practical simulation scenarios are generated from a corpus of data regarding actual incidents, near-miss events, disengagements (e.g., a situation in which a semi-autonomous or autonomous vehicle is returned to manual control from autonomous control), interruptions, events, and/or recordings. These simulation scenarios may be challenging, adversarial, or risky, which would be effective for developing solutions to mitigate or eliminate risk of accidents or incidents. Moreover, the additional scenarios include logical extensions or variations that are generated from the seed scenarios. The additional scenarios include additional realistic driving situations, in order to expand upon knowledge or information from the corpus of data. Moreover, even when a limited corpus of data is ingested or inputted into the computing system or the machine learning components, a sufficient number of scenarios may be derived and/or obtained. Therefore, all generated scenarios, from the seed scenarios to the additional scenarios, arise from actual real-life data, rather than being randomly created and potentially not grounded in reality. As a result, the realistic simulation scenarios effectively prepare an autonomous vehicle to become aware of and respond to a wide spectrum of different driving situations safely.

Further advantages include consistently defining a set of criteria. Often, information in a database may include relatively subjective criteria, such as a severity of an accident and/or an injury. Here, one or more machine learning components may be trained to infer, predict or determine criteria such as a severity. During the training, the machine learning components may ingest information regarding specific requirements or aspects of each category or classification of severity, such as minor, normal, or severe.

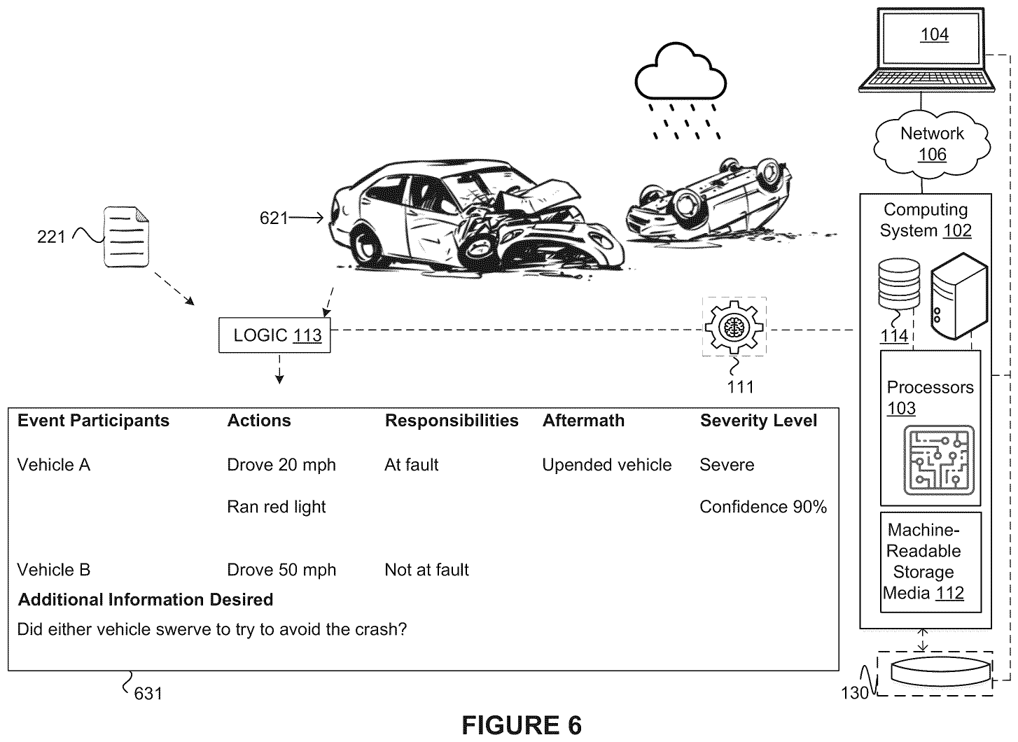

Moreover, the machine learning components may further output a confidence level or probability of each individual aspect (e.g., a vehicle or vehicle characteristic, a navigational characteristic, or an environmental characteristic) or of an overall output or file. For example, a confidence level may correspond to a determination or prediction of a severity level or degree, such as, a 90 percent confidence level of an accident being severe. In some examples, the machine learning components may further output or indicate specific information or a specific category of information that, if provided, would, or potentially would, increase a confidence level by at least a threshold amount, as will be illustrated in FIG. 6. In such a manner, the training of the machine learning components may be a catalyst that results in generating or obtaining more comprehensive repository of accident or incident information.

FIG. 1 illustrates an example implementation or scenario (hereinafter “implementation”), of a computing system 102 that automatically generates seed scenarios from a corpus of data which may encompass accident reconstruction reports, accident reports, incident reports, potential or suspicious activity reports, traffic reports, and/or other reports of actual events, accidents, near-miss events, or disengagements (hereinafter “events”). These aforementioned reports may be obtained from one or more external data sources, such as the German In Depth Accident Study (GIDAS), National Highway Traffic Safety Administration (NHTSA), Strategic Highway Research Program 2 (SHRP2), police reports, and/or citizen reports. The computing system 102 may obtain or ingest the corpus of data, parse and infer informational content from the corpus of data, and predict, determine, or generate a seed scenario from the corpus of data. The scenario may be manifested as a representation of the corpus of data, and may be in a form of a text file or document that includes geographical information and event information, which may encompass event participants and actions. Furthermore, the computing system 102 and/or a different computing system (e.g., computing system 152) may generate additional scenarios from the seed scenario, by modifying the seed scenario based on different geographical information, and/or different characteristics, actions, and/or parameters.

The implementation 100 can include at least one computing device 104 which may be operated by an entity such as a user. The user may submit a request or query through the computing device 104. The computing device 104 may receive the request or query from the user or from another computing device, computing process, or pipeline. Such a request or query may relate or pertain to operations to generate one or more scenarios, which may include seed scenarios and/or additional scenarios. A portion or all of the results including the scenarios and associated metadata may be stored in a database 130. In general, the user can interact with the database 130 directly or over a network 106, for example, through one or more graphical user interfaces, application programming interfaces (APIs), and/or webhooks. The computing device 104 may include one or more processors and memory. In some examples, the computing device 104 may visually render any outputs generated, such as the scenarios.

The computing system 102 may include one or more processors 103 which may be configured to perform various operations by interpreting machine-readable instructions, for example, from a machine-readable storage media 112. In some examples, one or more of the processors 103 may be combined or integrated into a single processor, and some or all functions performed by one or more of the processors 103 may not be spatially separated, but instead may be performed by a common processor. The processors 103 may be physical or virtual entities. For example, as virtual entities, the processors 103 may be encompassed within, or manifested as, a program within a cloud environment. The processors 103 may constitute separate programs or applications compared to machine learning components. The computing system 102 may also include a storage 114, which may include a cache for faster access compared to the database 130.

The processors 103 may further be connected to, include, or be embedded with logic 113 which, for example, may include, store, and/or encapsulate instructions that are executed to carry out the functions of the processors 103. In general, the logic 113 may be implemented, in whole or in part, as software that is capable of running on the computing system 102, and may be read or executed from the machine-readable storage media 112. The logic 113 may include, as nonlimiting examples, parameters, expressions, functions, arguments, evaluations, conditions, and/or code. Here, in some examples, the logic 113 encompasses functions of or related to processing and/or analysis of a corpus of data in order to generate scenarios, which may include a text file or document. Additionally or alternatively, the logic 113 may generate a media representation, such as an image or a video, of the scenario. Functions or operations described with respect to the logic 113 may be associated with a single processor or multiple processors. Functions or operations within the logic 113 will be subsequently described, following a description of the database 130.

The database 130 may include, or be capable of obtaining, a corpus of data, which may include structured and/or unstructured data, including text or media. This information may be ingested, and/or originate from, one or more different data sources. The database 130 may, additionally or alternatively, store one or more different representations of the corpus of data. For example, a representation may include an augmented or annotated version, which may include textual data, that has been augmented by any labels and/or annotations which describes one or more ontological characteristics, such as objects, entities, events, activities, and/or inferences. As a particular example, annotations may correspond to bounding boxes that delineate boundaries of entities. The database 130 may also store the corpus of data in raw form, meaning that the corpus of data has not been annotated, modified, and/or labeled. The database 130 may also store one or more results such as scenarios generated and evaluations regarding the generated results, for example, indicative of a probability or confidence level regarding a veracity or validity of a generated result. The probability or confidence level (hereinafter “confidence level”) may correspond to a probability that a generated scenario is indeed accurately described or represented, or accurately represents a scenario that actually occurred. Additionally or alternatively, the confidence level may correspond to a probability that the generated scenario is instructive or useful. Such a generated scenario may provide information or insights upon a simulation being run. For example, changing certain parameters or attributes in the generated scenario may result in avoiding or mitigating damage upon a simulation being run using the changed generated scenario.

The database 130 may also store any intermediate or final outputs from training of a machine learning component 111, results outputted as a result of execution by the machine learning component 111, and/or attributes, such as feature weights, corresponding to and/or determined or inferred by the machine learning component 111.

The logic 113 may be configured to perform processing and/or analysis functions by ingesting, obtaining, or receiving a corpus of data, including raw data (hereinafter “raw data”) 121 and/or source data 122, such as textual information from one or more databases. In some examples, the raw data 121 and the source data 122 can be the same. The logic 113 may generate a preamble and/or a prompt (hereinafter “prompt”) in order to obtain the corpus of data, process, analyze, and/or transform the obtained data. In some examples, the raw data 121 and/or the source data 122 may be obtained using a crawler 128, such as a web crawler, and/or through an application programming interface (API) 129. For example, the logic 113 may implement an API call via a wrapper or interface. The logic 113 may output or generate a queue encompassing the corpus of data to be processed following ingestion. In some examples, the logic 113 may ingest additional data such as data of other formats such as media, including image data, audio, video, and/or unstructured data, and/or sensor data from sensors including Lidar sensors, radar sensors, cameras, GPS, sonar, ultrasonic, IMU (inertial measurement unit), accelerometers, gyroscopes, magnetometers, and FIR (far infrared) sensors. For example, the logic 113 may ingest other relevant data including image data 123 or video data which may be captured by a camera, such as a traffic camera, stationary camera, or a vehicle camera, point cloud data 124 which may be captured by a Lidar sensor, audio data 125 (e.g., an emergency recording or other recording), for example manifested as a spectrogram, which may be captured by an audio sensor, geographical data 126 such as that captured by a GPS or GNSS, and/or map data 127 such as data from a satellite map.

The computing system 102 may also include, be associated with, and/or be implemented in conjunction with, the one or more machine learning components 111, which may encompass a large language model (LLM). The machine learning components 111 may be trained to perform and/or execute certain functions, such as ingesting input data including the raw data 121 and/or the source data 122, and/or the additional data, and transforming the raw data 121 and/or the source data 122, with or without augmentation from additional data and/or external data sources, to generate a scenario 131 from the inputs. In some examples, at least part of the raw data 121 and/or the source data 122 may be in different formats, such as abbreviations or shorthand. Therefore, the machine learning components 111 may transform the raw data 121 and/or the source data 122 into a standardized format. The scenario may be implemented as a seed scenario. In some examples, the machine learning components 111 may perform and/or execute the aforementioned functions in conjunction with the logic 113. Thus, any operations or any reference to the machine learning components 111 may be understood to potentially be implemented in conjunction with the logic 113 and/or the computing system 102. The scenario 131 may be manifested as a text file or document, and in some examples, may be separated into multiple files or documents. For instance, a first file 141 may include geographical information and other stationary entities, such as objects, geographical landmarks, traffic signs, road geometry, and/or environmental conditions while a second file 142 may include information or details regarding moving entities and/or their particular actions, such as those of vehicles (e.g., an ego vehicle) and/or pedestrians. In some implementations, the first file 141 may include any version, present or future, of an OpenScenario based file while the second file 142 may include any version, present or future, of an OpenDrive based file. In some examples, the first file 141 and/or the second file 142 may be stored in the database 130 and/or some other storage.

The machine learning components 111, in some examples, may decipher, translate, elucidate, or interpret information from the raw data 121 and/or the source data 122, and/or the additional data, in order to extract or obtain relevant information content from the raw data 121 and/or the source data 122. The machine learning components 111 may organize or parse the raw data 121 and/or the source data 122 according to an ontological framework or template (hereinafter “framework”). This ontological framework may include a criteria or guideline of object types and attributes to be extracted from the raw data 121 and/or the source data 122. For example, the ontological framework may include object types and mandatory and/or permissive ontological characteristics including attributes and links of each of the object types, and/or information of general ontological concepts associated with or required for the first file 141 and/or the second file 142, which may include OpenScenario based files and/or OpenDrive based files. In particular, the ontological framework may include objects, entities, and/or concepts such as a vehicle and/or a pedestrian, environmental entities such as a building, a road, a traffic sign, and concepts such as a crash, as well as attributes or characteristics of, or pertaining to, the objects, entities, and/or concepts associated with or required for the first file 141 and/or the second file 142. Thus, forming, creating, or generating the ontological framework may include parsing, separating, classifying, categorizing, or characterizing specific segments or portions of the raw data 121 and/or the source data 122 into certain objects, entities, and/or concepts. For example, permissive ontological characteristics stipulate an attribute or a link that an object is permitted to have, under a particular classification. One such exemplary permissive ontological characteristic may be that a vehicle object is permitted to have an attribute of either a type of vehicle, such as car, truck, bus, tractor, construction vehicle, emergency vehicle, plane, boat, or any applicable vehicle, or a license plate number, in order to be classified as a vehicle object. In other words, a mention or a reference of such an attribute would indicate or imply to the machine learning components 111 an existence of a vehicle. As another example, a permissive ontological characteristic may include a permissive link, such as specifying that in order to be classified as a vehicle, a particular object is permitted to have a link to a person with an ownership relationship, which may be uncovered by external information from an external data source, or from the raw data 121 and/or the source data 122 itself. As yet another example, a particular object may be defined or characterized using a prohibited attribute or a link, meaning that in order to be classified under a particular classification, that particular object cannot have the prohibited attribute or the prohibited link. One specific exemplary scenario is that wheels would be a prohibited attribute for a person object, meaning that if an object has wheels, then that object cannot be classified as a person, but may be classified as a vehicle. In other words, a mention of a wheel or tire would indicate to the machine learning components 111 an existence of a vehicle, but not of a person.

The machine learning components 111 may separate, divide, or partition (hereinafter “separate”) the raw data 121 and/or the source data 122 into one or more sections, segments, or partitions (hereinafter “sections”) according to ontological entities, objects, or concepts, as mentioned above. Each section may have a different category or classification, such as a type of entity (e.g., a vehicle, a pedestrian, a building, or a street) or an incident. Each category or classification may include attributes such as a model of a vehicle, a speed of the vehicle, identification information such as license plate number or license number, a severity of an incident, parties or entities involved in the incident, a location of the incident, and/or a time of the incident. The machine learning components 111 may categorize or separate each sentence in the raw data 121 and/or the source data 122 or portion thereof into a different category or classification. The machine learning components 111 may separate or categorize each sentence or portion thereof based on keyword recognition by comparing with an internal lexicon within the computing system 102 and/or within the database 130, analysis of sequences, patterns, syntax, grammar, formatting, and proximity of certain phrases, words, categories or types of the words and patterns thereof. For example, the machine learning components 111 may recognize any keywords such as “vehicle,” “car,” “truck,” and/or specific mentions of vehicle models, and synonyms thereof, as falling upon, or likely to fall under, the category of vehicles. Furthermore, the machine learning components 111 may recognize any phrases that include any of the aforementioned keywords as falling under description of vehicles or vehicle activities. The machine learning components 111 may also recognize certain related verbs, tenses, and participles thereof as connoting or suggesting an object such as a vehicle. For example, the machine learning components 111 may recognize verbs such as “drive,” “navigate,” or “steer” as indicative or suggestive of a vehicle. In particular, if an entity is mentioned, within a certain number of characters or words as a verb, that the machine learning components 111 identify as having some probability of being a vehicle, the machine learning components 111 may infer or determine an increased likelihood or probability that the entity refers to a vehicle. In such a manner, the machine learning components 111 may evaluate a proximity between different words suggestive or indicative of different entity types, common entity types, or related entity types, and recognize and/or identify particular figures of speech, such as nouns, pronouns, verbs, adjectives, adverbs, prepositions, and conjunctions, and proximity or relationships between words having different or same figures of speech. Regarding formatting, the machine learning components 111 may recognize certain formatting as being indicative or suggestive or certain details, such as time or location.

In some examples, following the generating of the scenario 131, the machine learning components 111, and/or different machine learning components 161, as implemented as part of a different computing system 152, may generate one or more additional scenarios 181 and/or 182. The additional scenario 181 may be generated based on extending or modifying the scenario 131 over or across a different physical location. For example, the different physical location may have at least a threshold degree of similarity in comparison with a location at which the scenario 131 was generated. Thus, the entities, such as the vehicles and/or the pedestrians, and their actions, may be maintained or unchanged as in the scenario 131, but the location and environmental aspects may be changed in the additional scenario 181. For example, the additional scenario 181 may have wider or narrower lanes, an absence or presence of safety railings on sides of lanes, an absence or presence of center dividers, and/or different weather and/or environment conditions such as different visibility level, AQI, road surface conditions, lane markings, and/or traffic signs which distinguish from the scenario 131. Meanwhile, the additional scenario 182 may be generated based on extending or modifying the scenario 131 over or across different characteristics, parameters, and/or ranges thereof. For example, the additional scenario 182 may be generated based on modifications of vehicle or navigational behaviors such as speed, signaling, lane changing, and/or swerving, modifications of pedestrian behaviors, and/or different airbag deployment characteristics. Therefore, by starting with a seed scenario (e.g., the scenario 131), the additional scenarios 181 and 182 generated may have a relatively high likelihood of being realistic and instructive. In some examples, each of the additional scenarios 181 and 182 can comprise at least two text or data files that can be used to simulate the driving environment described in the additional scenarios 181 and 182. In some examples, the at least two text files can comprise a OpenScenario file and a OpenDrive file. In such examples, the OpenScenario file and the OpenDrive file can be used for simulating the driving environment described in the additional scenarios 181 and 182. Simulating the driving environment may include displaying, rendering, or populating a model or output (e.g., a graphical, pictorial, and/or textual model) that encompasses or represents the entities, objects, and other features within the OpenScenario file and the OpenDrive file.

In some examples, the different computing system 152 may be implemented in a same, analogous, or similar manner as the computing system 102. The computing system 152 may include, or be associated with one or more processors 153, machine-readable storage media 162, a storage 164, and a database 180, which may be implemented in a same, analogous, or similar manner as the one or more processors 103, the machine-readable storage media 112, the storage 114, and the database 130.

FIG. 2 illustrates an implementation of the computing system 102, for example, in obtaining or ingesting (hereinafter “ingesting”) raw data 221, which may be implemented as the raw data 121 and/or the source data 122, and outputting or generating a scenario 231, which may be implemented as the scenario 131 or part of the scenario 131, as previously described with respect to FIG. 1. In particular, the logic 113 and/or the machine learning components 111 may obtain or extract relevant information such as participants, entities, agents, and/or actors (hereinafter “participants”) of an event, accident, disengagement, or incident (hereinafter “accident”) and incorporate such relevant information within the scenario 231. Here, the scenario 231 illustrates or includes information of participants and their characteristics or behaviors. The logic 113 may obtain information regarding one or more specific vehicles, pedestrians, and/or other moving or movable entities such as animals involved in the accident, as well as attributes or characteristics (hereinafter “characteristics”) thereof. For vehicles, the characteristics may include previously aforementioned characteristics, including models, identifying information such as license plate numbers, colors, airbag deployment characteristics, damage sustained, airbag deployment attributes, degree or extent of windshield transparency and/or tint, any actions taken on the vehicles following the accident, and/or historical information such as previous accidents, maintenance, and/or repairs. The logic 113 may further obtain information regarding actions of the entities and incorporate such information within the scenario 231. For example, these actions may include navigation characteristics such as speed, acceleration, braking force, direction of travel, any violations, and/or any other driving behaviors, such as swerving, turning, accelerating, decelerating or braking, and/or changing gears, within a threshold time of occurrence of an accident. The logic 113 may further determine or evaluate (hereinafter “evaluate”) a degree of responsibility or fault of any or each of the participants. During generating of the scenario 231, the logic 113 may transform or change a format of the raw data 221. Although FIG. 2 illustrates the scenario 231 being in a table format for the sake of example, other formats are also contemplate. For example, the logic 113 may transform unstructured data or some other format of data within the raw data 221 into a structured format, such as an object-oriented format, a JavaScript Object Notation (JSON) format, a graphical format, a list format (e.g., a list of entities with properties beneath each of the respective entities), a table format, or any format that lists entities (e.g., vehicles) in association with their characteristics. In some examples, the logic 113 may output or generate the scenario 231 in a structured format compatible with OpenDrive and OpenScenario syntax. For example, the logic 113 based on the scenario 231 can generate one OpenDrive file and one OpenScenario file. The OpenDrive file and the OpenScenario file can later be used to simulate, in a simulator, driving environment described in the scenario 231.

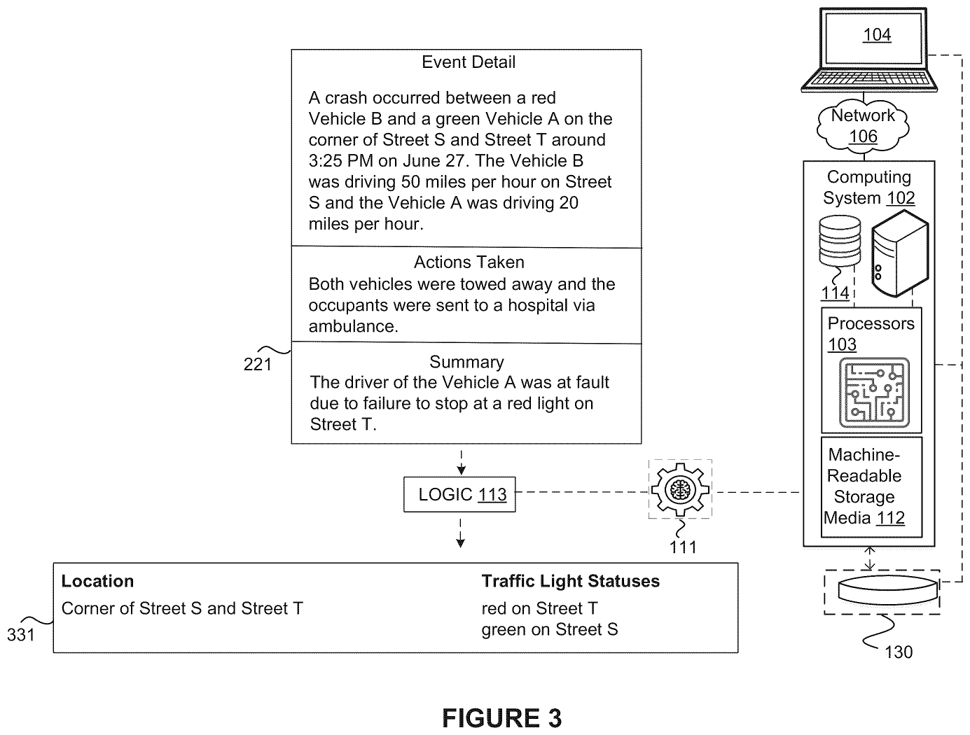

FIG. 3 illustrates an implementation of the computing system 102, for example, in obtaining or ingesting (hereinafter “ingesting”) raw data 221, which may be implemented as the raw data 121 and/or the source data 122, and outputting or generating a scenario 331, which may be implemented as the scenario 131 or part of the scenario 131. While the scenario 231 illustrates information of participants and their characteristics or behaviors, the scenario 331 illustrates information of environmental characteristics, such as a location of where an accident occurred, traffic light statuses at a time of the accident, and other relevant conditions such as weather, sunlight angle, visibility, smog, AQI, weather conditions, road conditions and/or surface attributes or materials of a road, shrubbery conditions, environmental characteristics such as road profile, road geometry, road signs, road markings, any barriers (e.g., safety barriers on a side of a road), traffic density and/or distribution, turn signals or signals from other vehicles or pedestrians, textures and colors of surround static or moving objects, lighting, shadows, and/or an angle of sunlight with respect to an occupant in a vehicle. The scenarios 231 and/or 331 may be manifested as files or documents. Any principles described with respect to the scenario 231 may also be applicable to the scenario 331, besides the different categories of information.

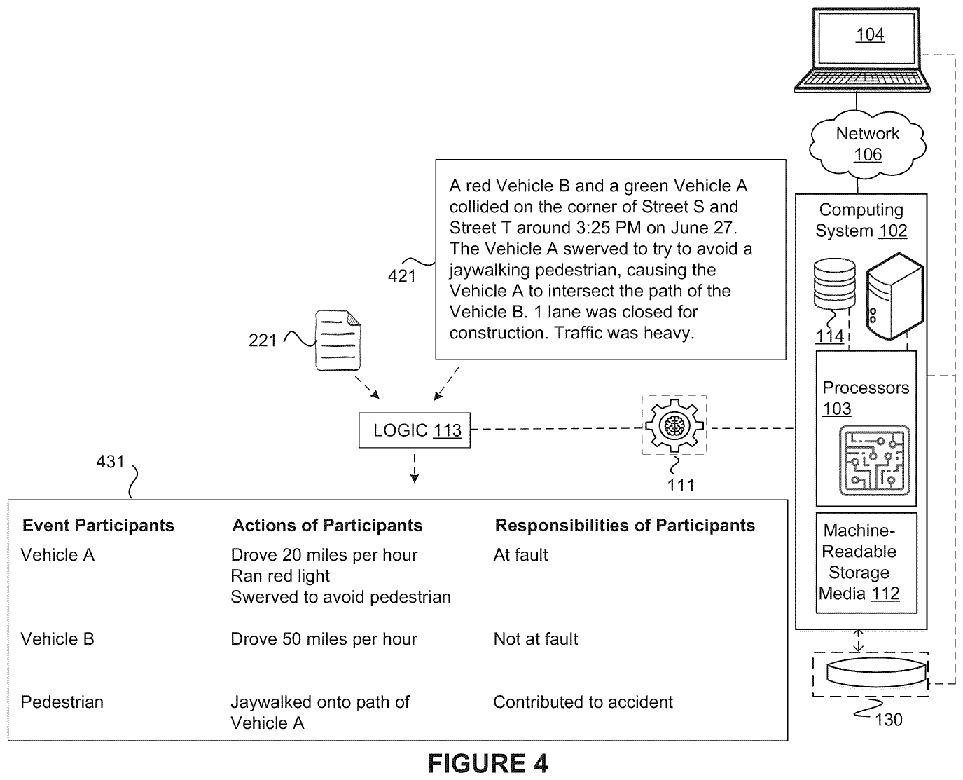

In some examples, the logic 113 may ingest additional data from one or more external sources such as external repositories or databases in order to enhance or augment an output of a scenario. For example, in FIG. 4, the logic 113 may ingest, in addition to the raw data 221, raw data 421 to supplement or augment the raw data 221. In some examples, the raw data 421 and the raw data 221 may both be textual sources of data. In some examples, the logic 113 may ingest both the raw data 221 and the raw data 421 nearly simultaneously or at different times. The logic 113 may predict, infer, or determine that the raw data 221 and the raw data 421 refer to a common event. The logic 113 may determine the raw data 421 as specifically pertaining to or describing a same event as the raw data 221 based on criteria such as date and/or time of an event described and/or identification information of one or more entities involved in the event. Specifically, if the raw data 221 and the raw data 421 indicate dates and/or times within a threshold range of each other, and/or a common license plate number or driver's license number, the logic 113 may infer or determine that the raw data 221 and 421 include, and/or are describing a common event.

In other examples, the logic 113 may determine that the raw data 221 is incomplete or is missing certain information. The logic 113 may determine or predict a particular source from which to ingest additional data based on any missing information or type of missing information within the raw data 221, and/or particular external sources with a highest likelihood of supplying the missing information or type of missing information. The highest likelihood may be determined, for example, based on historical frequencies or occurrences of information or types of information being present within different external sources.

In some examples, the logic 113 may select a certain number of sources (e.g., raw data sources) to be combined based on one or more types or categories of information presented, relevancy of information presented, and/or historical reliability or accuracy of information presented. In particular, the logic 113 may determine a certain number of information sources as relevant or pertaining to an event, but may select a subset (e.g., all or a portion) of those sources to be combined when generating a scenario. In some examples, when combining multiple sources, the logic 113 may weigh or prioritize each source according to certain criteria, including accuracy or reliability, and/or relevance. For example, raw data from a police report may be weighed more heavily compared to raw data from a citizen report. Thus, if two sources have conflicting information, then the logic 113 may prioritize information from a higher weighted source. Additionally or alternatively, if certain information from a lower weighted source is uncorroborated, the logic 113 may disregard that information or assign a lower confidence level to that information.

Here, the raw data 421 indicates common entities, including a red Vehicle B, a green Vehicle A, same cross streets Street S and Street T, and a common date and time. Thus, the logic 113 may infer or determine that the raw data 221 and 421 are describing a common event. The logic 113 may generate a scenario 431 that may include not only the raw data 221 but also the raw data 421. The scenario 431 illustrates, depicts, or includes information of participants and their characteristics or behaviors. The raw data 421 may include additional information that a pedestrian was also a participant in the event described, and specific actions and/or responsibilities of the pedestrian. This additional information may also be incorporated or combined into the scenario 431, but this additional information is absent from the scenario 231 which only includes the raw data 221.

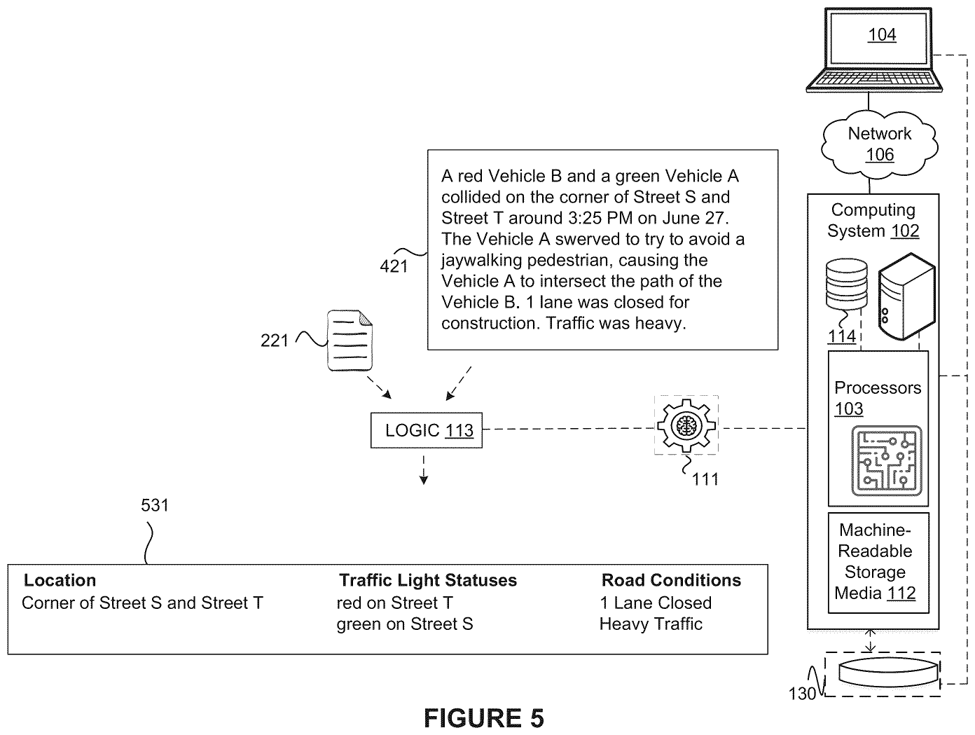

FIG. 5 illustrates an implementation of the computing system 102, for example, combining the raw data 221 and the raw data 421, and generating a scenario 531. While the scenario 431 illustrates or depicts information of participants and their characteristics or behaviors, the scenario 531 illustrates or depicts information of environmental characteristics. Specifically, in FIG. 5, the raw data 421 may include additional relevant information that one lane was closed on a road and that traffic was heavy. Such road conditions may be incorporated into the scenario 531, but are absent from the scenario 331, which only includes the raw data 221. In some implementations, the scenarios 431 and 531 may be manifested as separate files or documents. Thus, augmenting the raw data 221 with the raw data 421 may enhance or ameliorate a generated scenario, both in details of participants and environmental characteristics.

In some implementations, as illustrated in FIG. 6, to generate a scenario, not only may the logic 113 augment the raw data 221 with additional text sources such as the raw data 421, but the logic 113 may also augment the raw data 221 using other media, such as images, videos, audios, and/or digital smell or digital scent entities (e.g., files). In FIG. 6, the raw data 221 may be augmented by an image or a series of images (hereinafter “image”) 621. The image 621 may be within a same file or document as the raw data 221, or may be from a different file, document, or source compared to the raw data 221. For example, if the raw data 221 originated from a police report, the image 621 may be from the same police report, or may be from sensor data (e.g., the sensor data described in FIG. 1, such as the image data 123, the point cloud data 124, the audio data 125, the geographical data 126, the map data 127, and/or the digital scent entity 122), or may be from another source. In some examples, to augment the raw data 221, the logic 113 may search one or more sources for media pertaining to an event, such as a same accident or incident recorded by the raw data 221, or media captured at a particular time or interval of time, such as images and/or videos at a time that an event occurred.

In FIG. 6, the image 621 may provide additional information that following the accident, a vehicle was upended. The image 621 may have been captured in an exterior region of a vehicle. This information may have been missing from the raw data 221. Moreover, the logic 113 may perform media recognition, such as image recognition, which may encompass identifying bounding boxes corresponding to boundaries or outlines of entities and inferences regarding the entities based on movement across frames, relative placement, and/or configuration or shape of the entities. In particular, the logic 113 may infer, from the image 621, a severity level of the accident. Therefore, the logic 113 may generate a scenario 631 that is enriched with the additional information regarding an aftermath or a result of the accident as well as a severity level. In some examples, the logic 113 may also determine, infer, and/or output a confidence level or probability corresponding to the scenario 631 as a whole, and/or for one or more individual categories, types, or classifications of information within the scenario 631. For example, the logic 113 may infer that the severity level of the accident is severe, with a 90 percent confidence level that the severity level inference is correct. The logic 113 may infer the severity level based on certain criteria, such as an extent of damage to parties (e.g., vehicles), an extent of injuries, and/or whether a vehicle was upended. In some examples, the scenario 631 can comprise two text or data files that can be used to simulate the driving environment described in the scenario 631. In some examples, the two text files can comprise a OpenScenario file and a OpenDrive file. In such examples, the OpenScenario file and the OpenDrive file can be used for simulating the driving environment described in the scenario 631.

The logic 113 may also output additional information desired, which, if provided, may further increase the confidence level by more than a threshold amount. The additional information desired may be either part of the scenario 631, or stored separately from the scenario 631. For example, information of whether either vehicle in the accident swerved to try to avoid the accident may be especially instructive or useful in determining the severity level of the accident. In such a manner, the logic 113 may additionally provide feedback, for example, to a user of the computing device 104, to further improve the raw data 221 and/or other sources of data, and to make the raw data 221 more comprehensive and relevant.

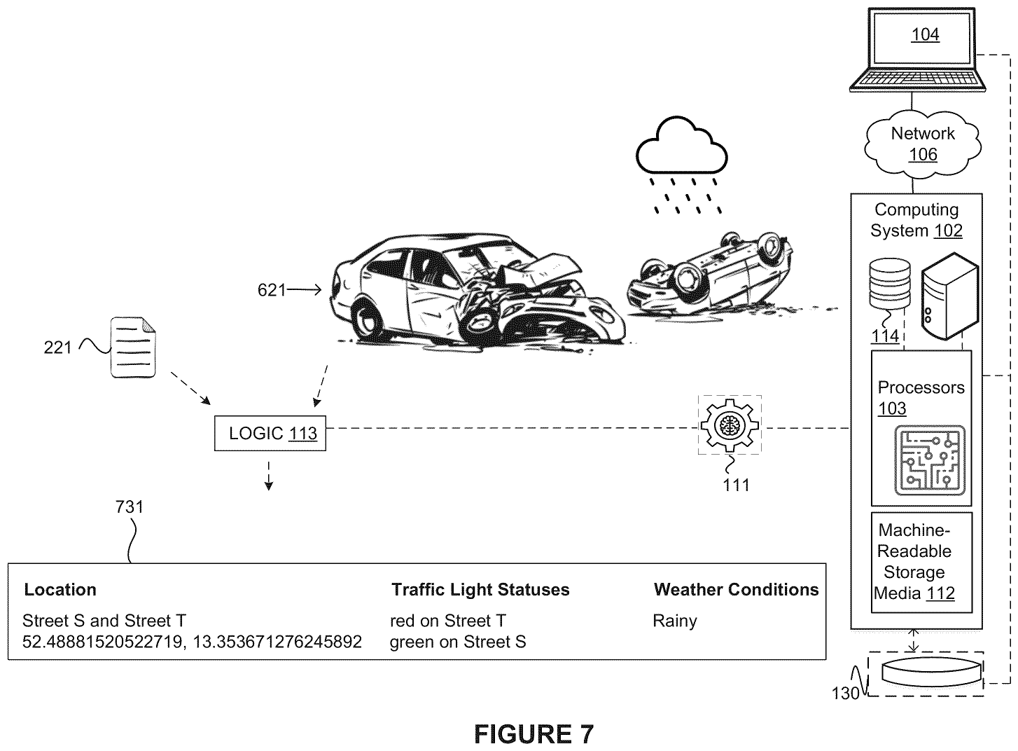

FIG. 7 illustrates an implementation of the computing system 102, for example, combining the raw data 221 and the image 621, and generating a scenario 731. While the scenario 631 illustrates or depicts information of participants and their characteristics or behaviors, the scenario 731 illustrates or depicts information of environmental characteristics. Specifically, in FIG. 7, the image 621 may include additional relevant information that weather conditions were rainy. Such weather conditions may be incorporated into the scenario 731, but are absent from the scenario 331, which only includes the raw data 221. In some implementations, the scenarios 631 and 731 may be manifested as separate files or documents. Thus, augmenting the raw data 221 with the image 621 may enhance or ameliorate a generated scenario, both in details of participants and environmental characteristics.

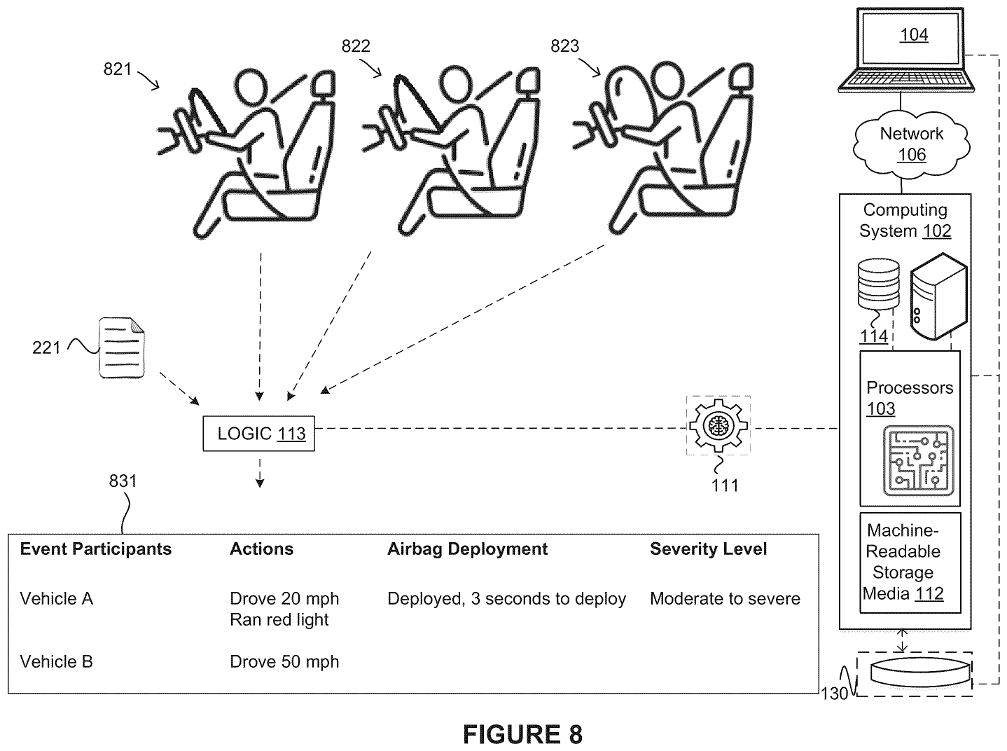

In some implementations, captured or obtained media from inside a vehicle may also enhance a generated scenario. Such media may depict changes within a vehicle and/or emotional states of one or more occupants. Emotional states may include a degree or extent of agitation, exasperation, panic, perturbation, and/or calmness, among other emotions. These emotional states may be inferred, by the logic 113, based on facial expressions and/or movements of the occupants. For example, in FIG. 8, a series or sequence of images (hereinafter “series of images”) 821, 822, 823, which may be captured from a video, may show an interior of a vehicle, in particular, showing changes within a vehicle such as an airbag deployment of the vehicle during the accident. The series of images 821, 822, 823, may be identified as pertaining to the accident based on timestamps of the series of images 821, 822, 823 corresponding to a time that the accident occurred. The logic 113 may augment the raw data 221 with the series of images 821, 822, 823 to generate a scenario 831, which depicts information of participants and their characteristics or behaviors. In particular, the scenario 831 may be augmented with information regarding airbag status and/or airbag deployment, including whether an airbag was deployed on a passenger and/or a driver side, an extent of deployment, and how long the deployment took. Additionally, the logic 113 may infer a severity level based on the series of images 821, 822, 823. For example, based on the airbag deploying, the logic 113 may infer the severity level of the accident as moderate to severe. The logic 113 may further corroborate information within the scenario 831, including the severity level, using other sources, such as other media and/text sources pertaining to the accident.

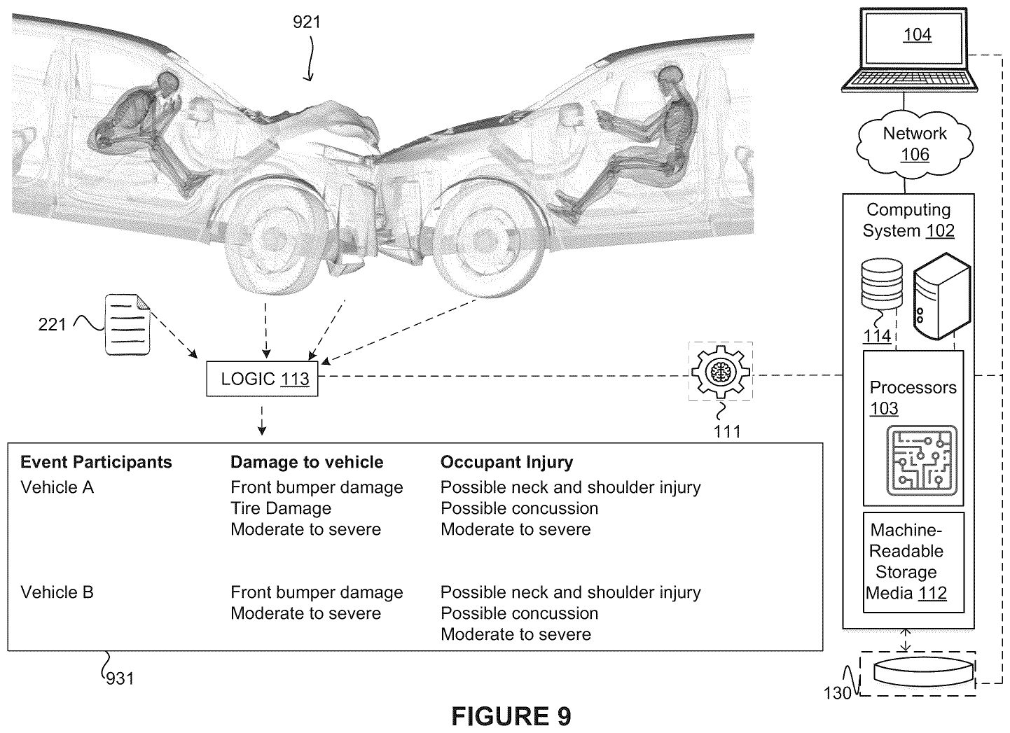

In some implementations, captured or obtained media from both an interior and an exterior of a vehicle may also enhance a generated scenario. For example, in FIG. 9, an image or video 921 (hereinafter “image”) may show a representation of both an interior and an exterior of one or more vehicles during an accident. The logic 113 may augment the raw data 221 with the image 921 to generate a scenario 931, which depicts information of participants and their characteristics or behaviors. In particular, the scenario 931 may be augmented with information regarding an extent, a status and/or severity level of an accident both in terms of property (e.g., vehicle) damage and occupant (e.g., human) injury. The logic 113 may infer, from an extent of an impact between two vehicles, movement, and/or forces exerted upon the vehicles and/or occupants, an extent and severity level of damage and injury in the scenario 931. As a result, the logic 113 may enhance and enrich the raw data 221 using information from media, specifically, from moving or movable entities, that may not have been fully captured in the raw data 221.

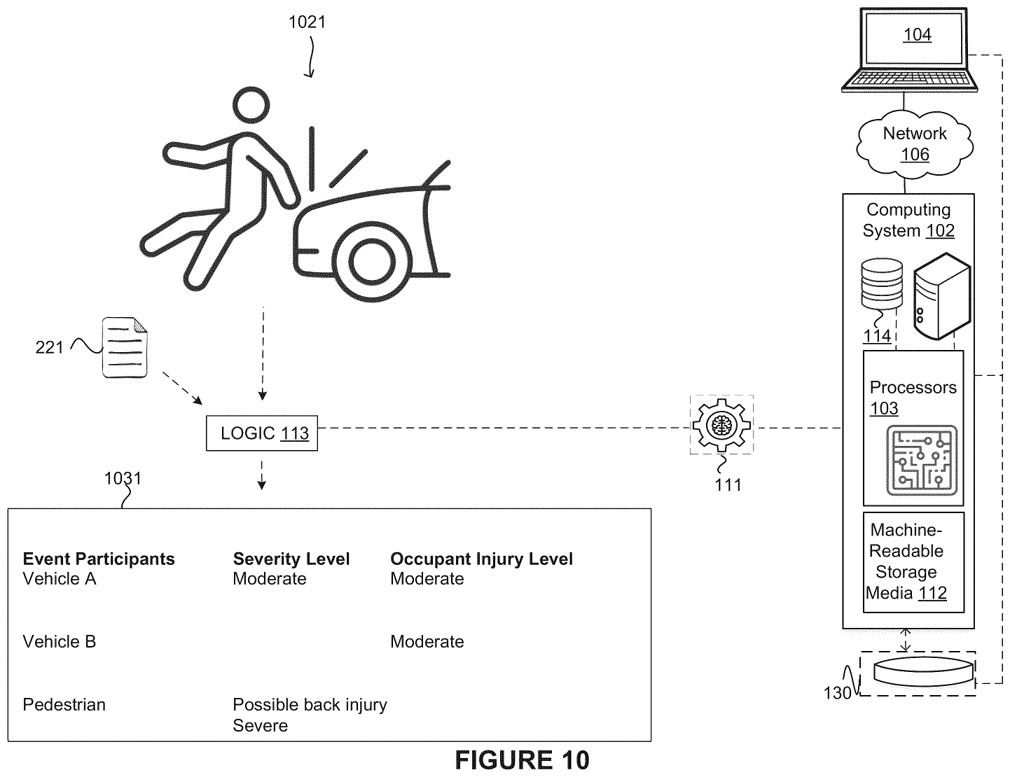

In some implementations, captured or obtained media from an exterior of a vehicle may also enhance a generated scenario by capturing interactions between a vehicle and a non-vehicular entity, such as a pedestrian. For example, in FIG. 10, an image or video 1021 (hereinafter “image”) may show a representation of an interaction, such as a collision, between a vehicle and a pedestrian. This interaction may have occurred in addition to, or during, a vehicle accident. The logic 113 may augment the raw data 221 with the image 1021 to generate a scenario 1031, which depicts information of participants and their characteristics or behaviors. In particular, the scenario 1031 may be augmented with information regarding an extent, a status and/or severity level of an accident both in terms of property (e.g., vehicle) damage and human injury, for example, inflicted upon a pedestrian. The logic 113 may infer, from an extent of an impact between two entities, in this scenario, between a vehicle and a non-vehicular entity, an extent and severity level of damage and injury in the scenario 1031. For example, the logic 113 may detect that a pedestrian was thrown at least a threshold distance as a result of an impact with a vehicle, and infer a severe injury to the pedestrian. As a result, the logic 113 may enhance and enrich the raw data 221 using information from media that may not have been fully captured in the raw data 221.

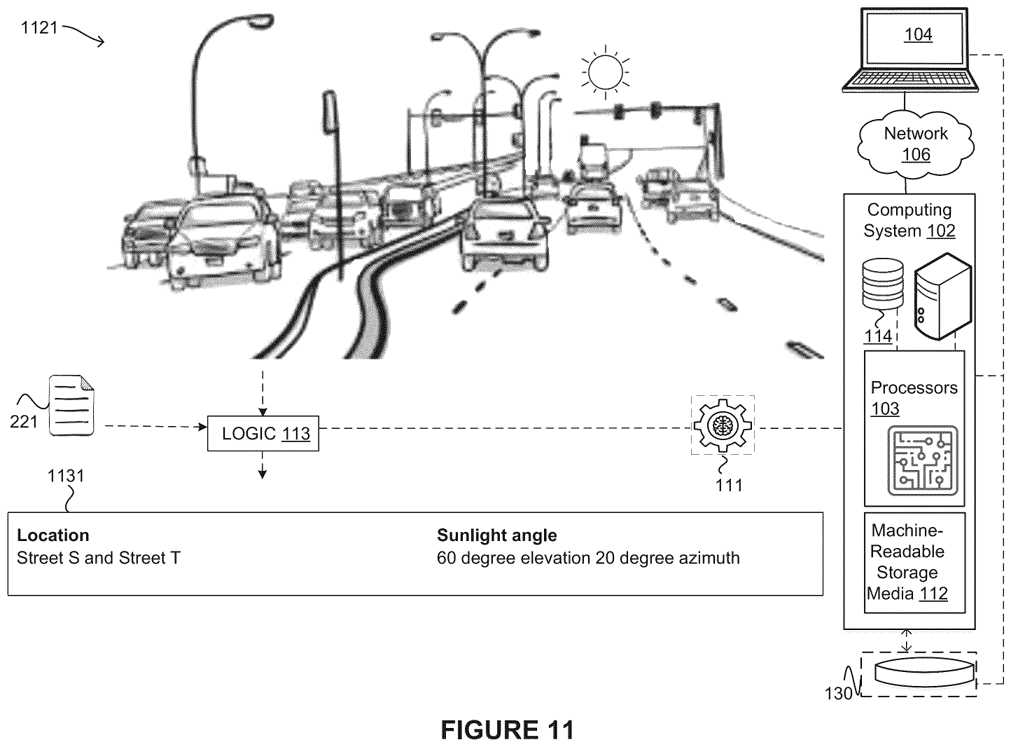

In some implementations, captured or obtained media from an exterior of a vehicle may also augment a generated scenario by providing additional information regarding environmental characteristics in relation to one or more participants of an event. For example, in FIG. 11, an image or video 1121 (hereinafter “image”) may show a representation of sunlight position and angle with respect to a vehicle, such as a vehicle near an accident or of a vehicle involved in an accident. Attributes or parameters such as a sunlight angle may have been a contributor in an accident. Thus, collecting such information from media may be instrumental in determining factors contributing to an accident, and ultimately, potentially mitigating or eliminating a risk caused by such factors. The logic 113 may augment the raw data 221 with the image 1121 to generate a scenario 1131, which captures a sunlight angle in the example of FIG. 11. The scenario 1131 depicts information of environmental characteristics.

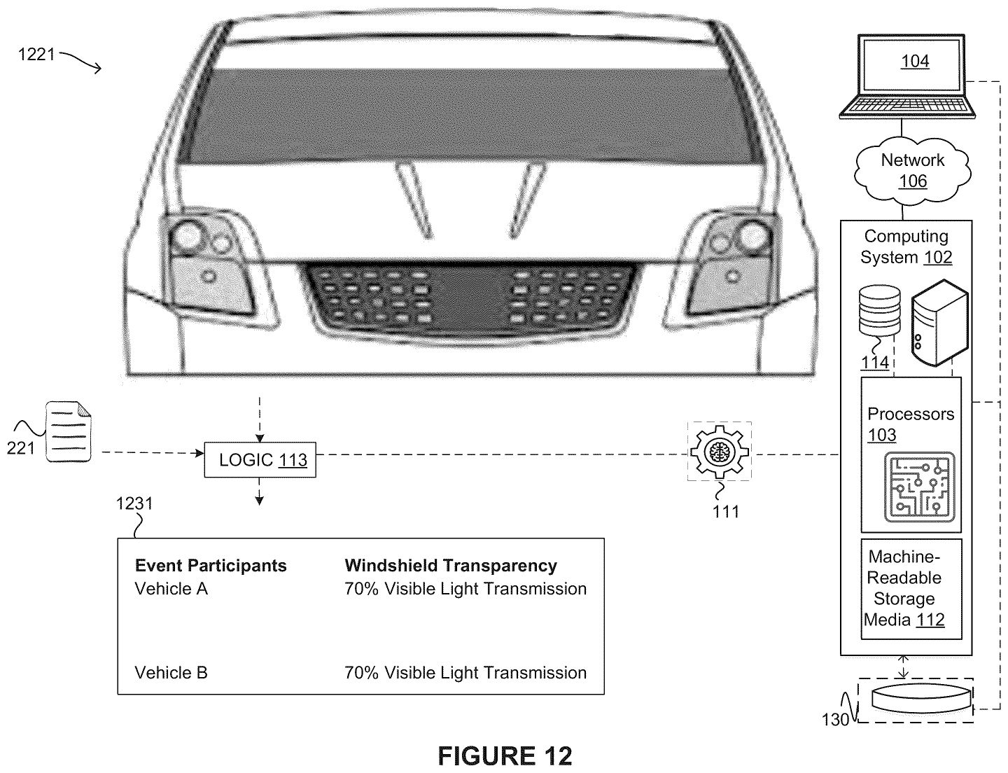

In some implementations, captured or obtained media from an exterior or an interior of a vehicle may also augment a generated scenario by providing additional information regarding characteristics in relation to one or more participants of an event, such as vehicle characteristics. For example, in FIG. 12, an image or video 1221 (hereinafter “image”) may show a representation of relatively static aspects of a vehicle, such as a windshield tint or windshield transparency of vehicles. Certain static aspects may contribute to an accident. Thus, collecting static aspects of a vehicle from media may aid in determining factors contributing to an accident, and ultimately, potentially mitigating or eliminating a risk caused by such factors. The logic 113 may augment the raw data 221 with the image 1221 to generate a scenario 1231, which captures a windshield transparency of one or more vehicles involved in an accident. The scenario 1231 depicts information of participants and their characteristics or behaviors.

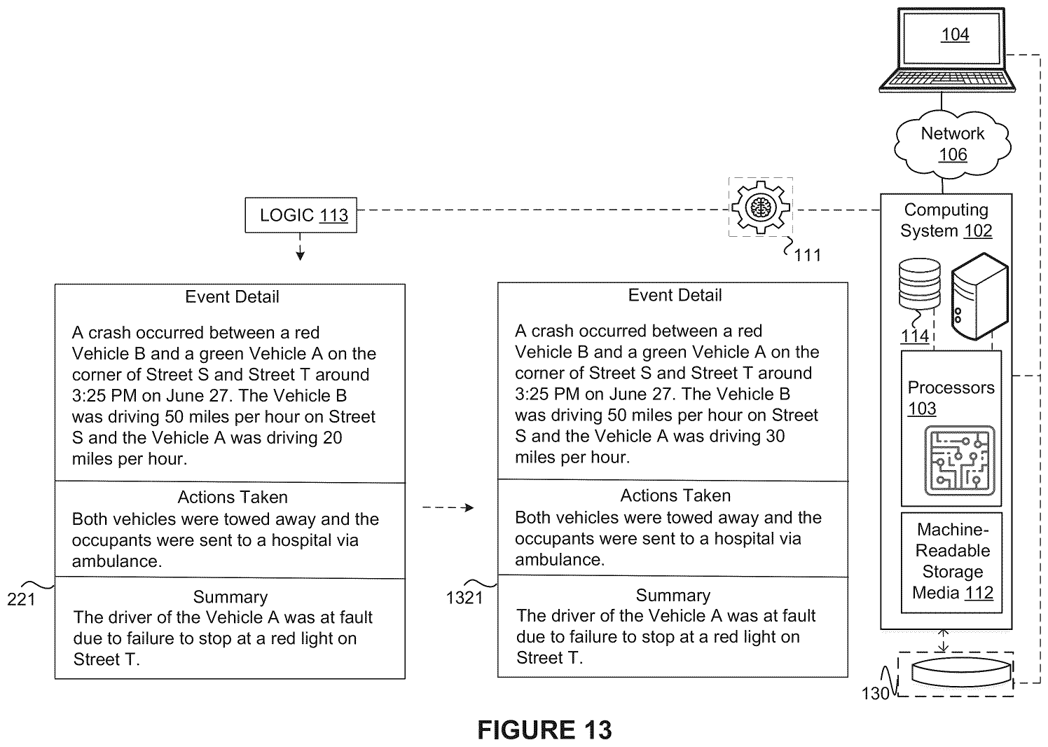

In some implementations, the logic 113 may infer, detect, or determine (hereinafter “infer”) one or more inaccuracies within the raw data 221. For example, the logic 113 may infer an inaccuracy as a result of a contradicting source of data, such as a media entity, and/or may logically infer that a particular condition within the raw data 221 is inaccurate, inconsistent and/or incompatible with other information (hereinafter “inaccurate”) within the raw data 221. For example, the logic 113 may infer that two vehicles travelling at certain speeds and/or angles could not have possibly sustained a certain level of damage in an accident, and therefore, the logic 113 may infer that some of the information within the raw data 221 may be inconsistent. The logic 113 may annotate or otherwise indicate such inaccuracy within the raw data 221, and/or may correct the raw data 221 to replace an inaccuracy with more accurate information, if verified or corroborated by other sources of data. For example, in FIG. 13, the logic 113 may revise a speed of one of the participants, such as, the vehicle A, from 20 miles per hour to 30 miles per hour, in modified raw data 1321. Such an implementation represents an additional benefit of verifying and correcting the raw data 221 so that if the raw data 221 is accessed in the future, the raw data 221 will present information that is more accurate or confirmed or determined to be accurate at a higher confidence level.

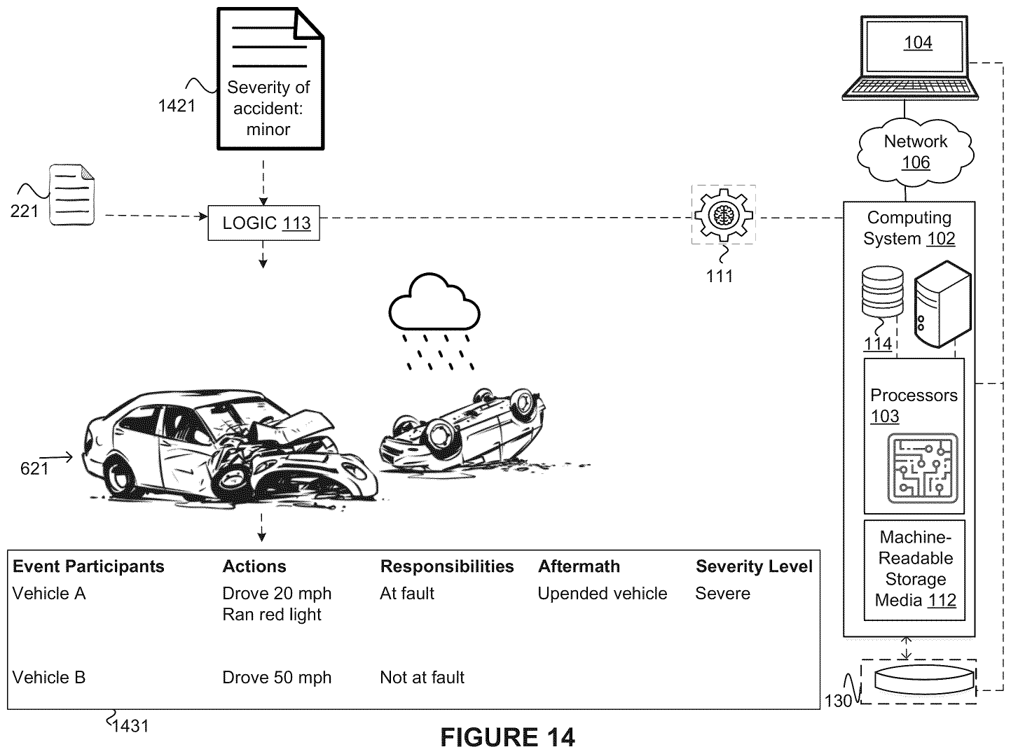

As explained above, in some implementations, during generation of a scenario, the logic 113 may process information that is conflicting, contradictory, inconsistent, or uncertain. Such inconsistencies may be attributed to different sources having different standards and/or definitions of certain terms. Therefore, the logic 113 generates a scenario that makes such definitions and/or standards uniform. For example, in FIG. 14, the logic 113 may ingest the raw data 221 and raw data 1421 describing a common event (e.g., accident). The logic 113 may interpret the raw data 221 to infer that a severity of an accident was moderate to severe. However, the raw data 1421 may indicate that a severity of the accident was minor. The logic 113 may resolve the potentially conflicting sources of information, the raw data 221 and the raw data 1421, based on types of the data (e.g., media or text), priorities and/or degrees of reliability of each source, and/or a level of detail provided by each source. For example, the logic 113 may weigh more heavily whichever source has a higher or highest priority or degree of reliability, or a higher or highest level of detail. Additionally or alternatively, the logic 113 may weigh a media file more heavily or with higher priority compared to a text file. Additionally or alternatively, the logic 113 may resolve the potentially conflicting sources of information by corroborating with another different source. For example, the logic 113 may obtain another source depicting or describing the same event, such as the image 621. From the image 621, the logic 113 may infer that the severity level was indeed severe, and that the raw data 1421 was incorrect or inaccurate and that the raw data 221 is accurate. The logic 113 may generate a scenario 1431 which incorporates the raw data 221 and the image 621, while entirely or partially disregarding the raw data 1421. As another example, the logic 113 may output a prompt indicating such an inconsistency and request feedback regarding the inconsistency. Upon receiving the feedback, the logic 113 may incorporate the feedback into the scenario 1431. The scenario 1431 depicts information of participants and their characteristics or behaviors.

Through such a learning process, the logic 113 may also adjust weights or priorities of different sources. For example, upon determining that the raw data 1421 was incorrect or inaccurate, the logic 113 may reduce a priority or a degree of reliability of the raw data 1421, Upon determining that the raw data 221 was correct or accurate, the logic 113 may increase a priority or a degree of reliability of the raw data 221. Through such a process, the logic 113 may more accurately assess reliability of data sources in order to better filter and extract relevant and reliable information while filtering out information of low reliability.

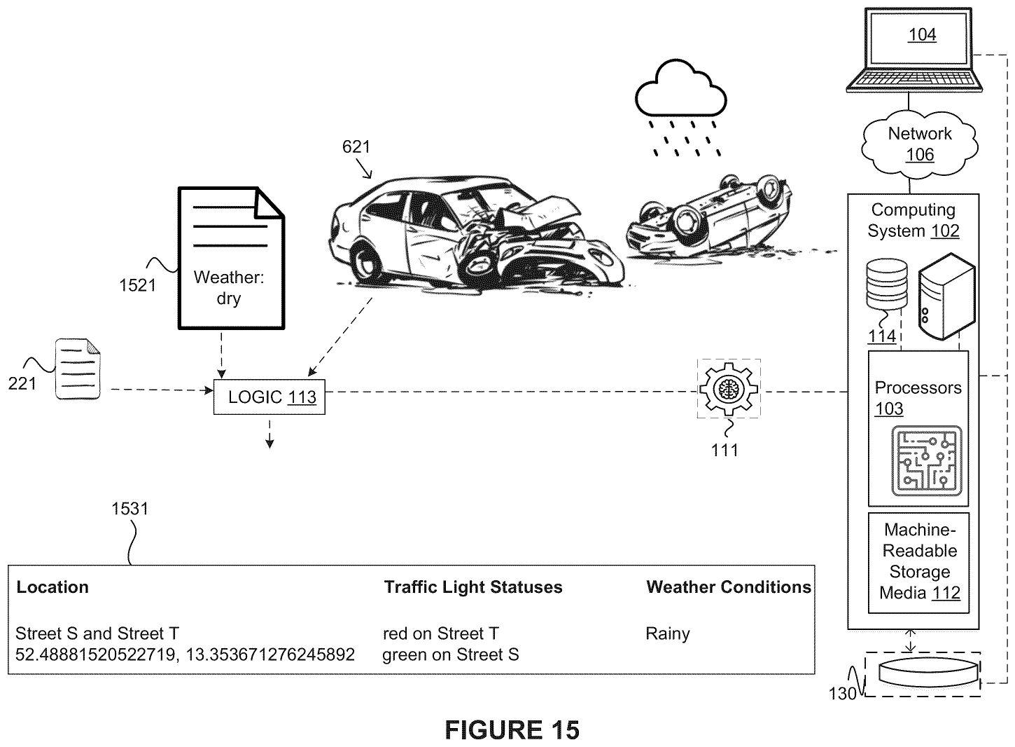

As another example of resolving conflicting information, in FIG. 15, the logic 113 may ingest the raw data 221, raw data 1521 and the image 621, which all describe a common event. The logic 113 may determine an inconsistency between the raw data 1521 which indicates that the weather was dry, and the image 621, which indicates that the weather was rainy. The logic 113 may resolve the inconsistency in favor of the image 621 because the image 621 may be a type of data that has a higher priority compared to text, which is a format that the raw data 1521 was presented in. Additionally or alternatively, the logic 113 may determine that the image 621 has a higher priority because the image 621 comes from a source that is more trusted or reliable compared to that of the raw data 1521. Upon resolving the inconsistency, the logic 113 may generate a scenario 1531 that incorporates the image 621 but partially or entirely disregards the raw data 1521. The scenario 1531 depicts information of environmental characteristics.

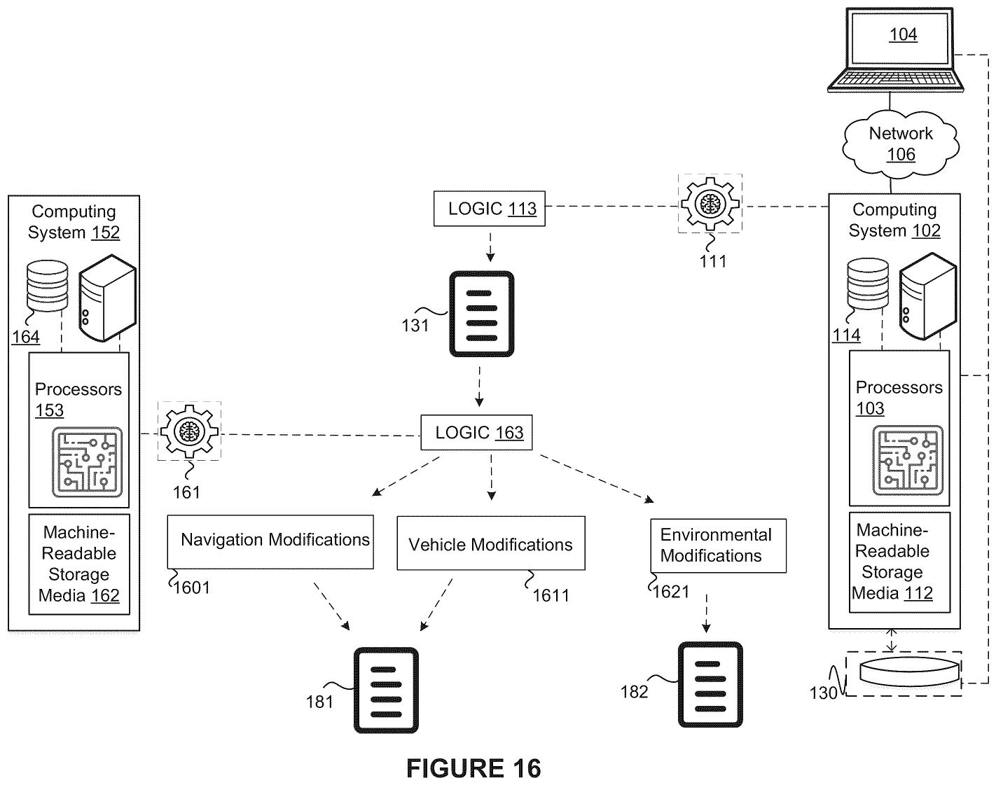

In the previous figures, the scenarios generated (e.g., the scenarios 131, 231, 331, 431, 531, 631, 731, 831, 931, 1031, 1131, 1231, 1331, 1431, 1531) may represent seed scenarios or portions thereof. Following the generating of the seed scenarios, the logic 113 and/or the logic 163 may expand the seed scenarios to generate additional scenarios, as illustrated in FIG. 16. The generating of additional scenarios may further include represent realistic occurrences for which preventive measures may feasibly be executed. For example, the logic 163 may modify the seed scenarios by adjusting any of navigation parameters, attributes, or characteristics (hereinafter “characteristics”), vehicle characteristics, and/or environmental characteristics. For example, the logic 163 may, from each of the seed scenarios or a subset of the seed scenarios, perform navigation modifications 1601 and/or vehicle modifications 1611 to generate the additional scenarios 181, and may perform environmental modifications 1621 to generate the additional scenarios 182. Examples of the navigation modifications 1601, the vehicle modifications 1611, and the environmental modifications 1621 have been previously enumerated and described, and several examples are further enumerated herein. The navigation modifications 1601 may encompass changes in speed, changes in braking (e.g., braking pressure), switching of gears, changes in driving styles, changes in signaling, changes in yielding, changes in lane switching, and/or modifications in pedestrian behaviors such as extents to which pedestrians yield and/or jaywalk. The vehicle modifications 1611 may encompass changes in airbag deployment characteristics, windshield tint or transparency, whether a vehicle is right-hand drive or left-hand drive, vehicle materials and upholstery, and/or vehicle communications characteristics either within the vehicle or with other vehicles. The environmental modifications 1621 may include changes in characteristics of lanes (e.g., width or markings of lanes), an absence or presence of safety railings on sides of lanes, an absence or presence of center dividers, different weather and/or environment conditions such as different visibility level, AQI, road surface conditions, and/or traffic signs, and/or whether a road is built for right-hand traffic or left-hand traffic. Specifically, one example of an environmental modification may be modifying certain traffic landmarks, such as traffic lights, from functional to nonfunctional, or vice versa. The additional scenarios may be simulated to identify or predict corresponding results, such as whether an accident could have been mitigated or avoided. The simulations may identify factors that may mitigate or exacerbate a risk and/or a severity of an accident. The generating of additional scenarios not only identifies specific modifications to vehicle controls and/or behaviors which could mitigate or eliminate a risk of an accident, but also possible improvements in environmental aspects such as traffic indicia that could mitigate or eliminate a risk of an accident.

In some examples, the logic 163 may generate a diverse range of different scenarios in which predicted results or aftermaths (e.g., crash rate distributions, crash type distributions, severity distributions, near-miss distributions) differ, and/or in which preventive measures to avoid an accident differ. The logic 163 may avoid generating repeated scenarios in which predicted results or aftermaths are the same or similar, and in which the preventive measures to avoid an accident are the same or similar. For example, in order to avoid a pedestrian who unexpectedly walks or runs onto a road, preventive measures may depend on whether or not a vehicle is following close behind within a threshold distance. Because suddenly braking might result in a following vehicle being unable to react and brake, if a vehicle is following within a threshold distance, a preventive measure may include swerving instead of braking. Thus, different scenarios of a pedestrian unexpectedly venturing onto a road may include a following vehicle within a threshold distance, or no following vehicle within a threshold distance. Because these two scenarios would involve or require different preventive measures, these two scenarios may be instructive in a process of learning different driving situations and preventive measures.

In some examples, the logic 163 may generate one or more additional scenarios, each of which encompasses a range of attributes and/or values. These attributes and/or values may not affect a preventive measure. For example, if another car were driving at between 40 and 60 miles per hour, predicted results or aftermaths may differ by less than threshold amounts or ranges, and/or a preventive measure to avoid an accident may be relatively unchanged. The logic 163 may generate a single scenario that encompasses another vehicle driving at between 40 and 60 miles per hour. Therefore, if two scenarios have a same or similar preventive measure, such as both scenarios having a preventive measure of swerving at a specific speed in order to avoid an accident, then these two scenarios may be combined, integrated, or synchronized into a single combined scenario, such as a single range or that encompasses multiple possibilities.

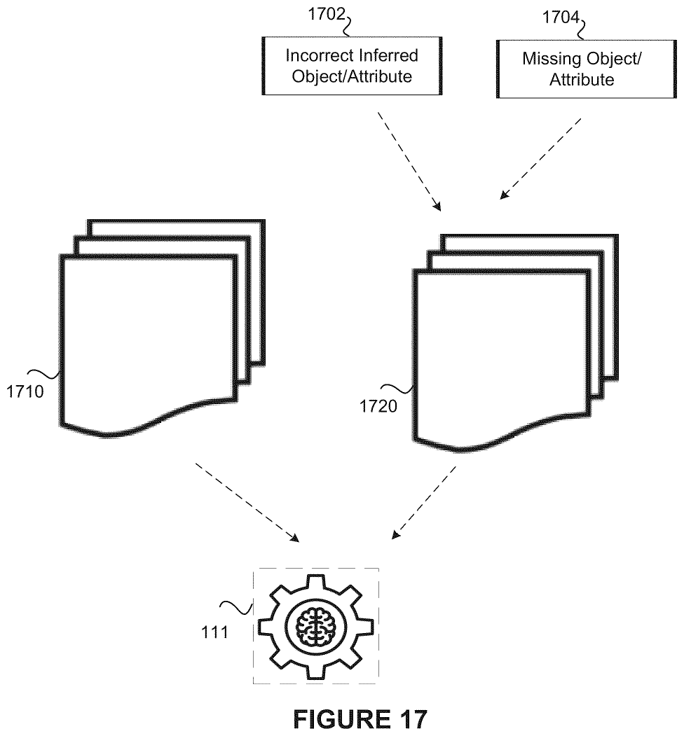

The machine learning components 111 may be trained in a sequential and iterative process to generate seed scenarios. The training may be performed in part by the computing system 102 and/or by a different computing system. FIG. 17 illustrates an example implementation of training of the machine learning components 111. For example, with respect to FIG. 17, the machine learning components 111 may be initially trained using a first training dataset 1710, and subsequently trained using a second training dataset 1720. The first training dataset 1710 may include examples or test scenarios (hereinafter “examples”) of different classifications, such as different severity levels of events, examples of transforming raw data into a scenario, and examples of augmenting raw data of a textual format with other raw data of a textual format and/or media, as illustrated in FIGS. 1-15. The first training dataset 1710 may include examples of correctly generated scenarios and/or incorrectly generated scenarios previously known before the machine learning components 111 generated any seed scenarios. These incorrectly generated scenarios may encompass pitfalls. The second training dataset 1720 may include compiled examples or test scenarios (hereinafter “examples”) 1702 and 1704, which may encompass, or be generated based on, incorrectly inferred objects or attributes and missing objects or attributes, respectively, by the machine learning components 111 during generating of the seed scenarios. For example, training using the second training dataset 1720 may occur following a set of inferences which were made at least partially incorrectly by the machine learning components 111. The examples 1702 and 1704 may encompass false positive detections of entities and/or attributes, and/or false negative detections of entities and/or attributes.

Specifically, the examples 1702 in which the machine learning components 111 previously incorrectly inferred an object or an attribute may include the machine learning components 111 inferring that a vehicle was a participant in an accident but in fact, the vehicle was not a participant but rather, was a witness, bystander, or another vehicle unrelated to the accident. As another example of an incorrectly inferred object or attribute, the machine learning components 111 may have inferred that a pedestrian was hit, or otherwise interacted with vehicles in an accident, but in fact, the pedestrian did not interact with any vehicles in the accident, and/or a different pedestrian interacted with the vehicles in the accident. As another example of an incorrectly inferred object or attribute, the machine learning components 111 may have inferred incorrect identification information associated with a vehicle or a person, such as an incorrect license plate number or an incorrect driver's license number. As another example of an incorrectly inferred object or attribute, the machine learning components 111 may have inferred an incorrect standard or classification, such as inferring that a severity level is moderate but in fact, the severity level was severe. As another example of an incorrectly inferred object or attribute, the machine learning components 111 may have inferred that one vehicle was at fault, but in fact no vehicle was at fault or a different vehicle was at fault. As another example of an incorrectly inferred object or attribute, the machine learning components 111 may have inferred that no vehicle was at fault, but in fact one vehicle was at fault. Such incorrect inferences may be attributed to any of incorrect recognition and/or translation of text, incorrect identification of one or more standards or classifications due to incorrect application of criteria in determining one or more standards or classifications, incorrectly weighing different sources of information, and/or incorrect assumptions regarding incomplete fields or incomplete information.

Meanwhile, the examples 1704 may in which the machine learning components 111 previously missed an inference of an object or an attribute may include the machine learning components 111 missing a detection of or failing to recognize a vehicle, a pedestrian, or other entity that was a participant in an accident. As another example of an incorrectly inferred object or attribute, the machine learning components 111 may have missed a detection of or failed to recognize a specific attribute of an entity, such as failing to recognize that airbags were deployed in a vehicle, or failing to recognize identification information such as a license plate number or a driver's license number. Such missing inferences may be attributed to any of incorrect recognition and/or translation of text, incorrectly weighing different sources of information, such as improperly disregarding or reducing a weight of certain sources of information, failing to associate different sources with a common event, and/or incorrect assumptions regarding incomplete fields or incomplete information. Thus, subsequent iterations or stages of training may further improve or confirm outputs, such as inferences, generated by the machine learning components 111.

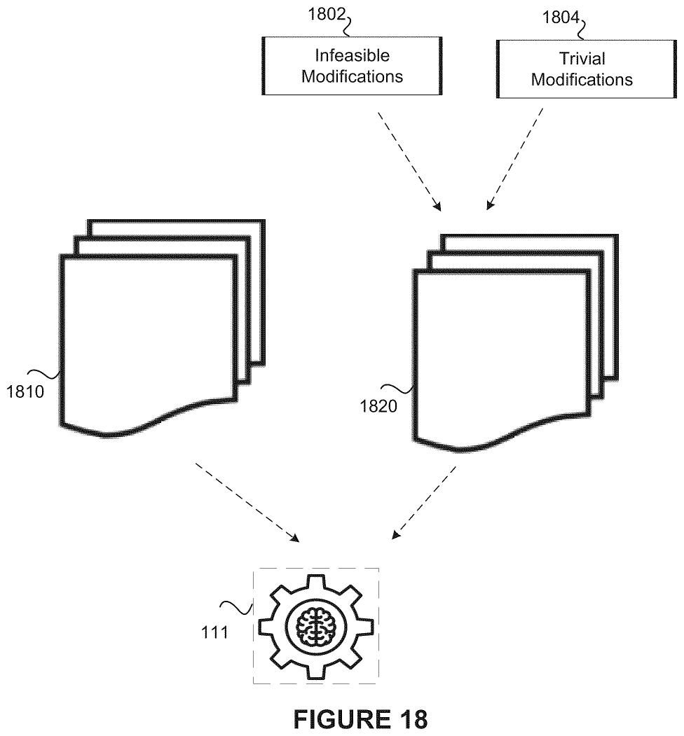

Similarly, the machine learning components 161, which may expand upon the seed scenarios to generate additional scenarios, may be trained in a sequential and iterative process. FIG. 18 illustrates an example implementation of training of the machine learning components 161. The training may be performed in part by the computing system 102 and/or by a different computing system. For example, with respect to FIG. 18, the machine learning components 161 may be initially trained using a first training dataset 1810, and subsequently trained using a second training dataset 1820. The first training dataset 1810 may include examples of additional scenarios generated from modifying certain attributes and/or parameters of seed scenarios, such as the navigation modifications 1601, the vehicle modifications 1611, and/or the environmental modifications 1621. The first training dataset 1810 may include examples of both modifications that are feasible and modifications that are nonsensical, such as a vehicle speeding up when approaching a curve, and/or a vehicle speeding up when approaching a red light. The first training dataset 1810 may include data that was previously known before the machine learning components 161 generated any additional scenarios from the seed scenario.

The second training dataset 1820 may include compiled examples or test scenarios (hereinafter “examples”) 1802 and 1804, which may encompass, or be generated based on, incorrect, redundant, and/or infeasible additional scenarios by the machine learning components 161. For example, infeasible additional scenarios may include unrealistic or nonsensical behaviors, and/or scenarios in which accident avoidance or mitigation is impossible or impractical. Redundant additional scenarios may include examples which are repetitive, such as those that have same or similar corresponding results. For example, redundant additional scenarios may not affect a likelihood and/or a severity of an accident, disengagement, or other event (hereinafter “event”), or would impact a likelihood and/or a severity by less than a threshold amount and/or less than a threshold probability, compared to a seed scenario. One particular example includes modifying a speed of a vehicle within a range of ten miles per hour, applying a braking force or pressure, or an accelerator force or pressure within certain ranges, which do not affect a likelihood and/or a severity of an event, or would impact a likelihood and/or a severity by less than a threshold amount and/or less than a threshold probability. Therefore, redundant scenarios may include modifications of speed, braking force or pressure, and/or accelerator force or pressure, of one or more vehicles, which impact a likelihood and/or a severity of an event by less than a threshold amount and/or less than a threshold probability.

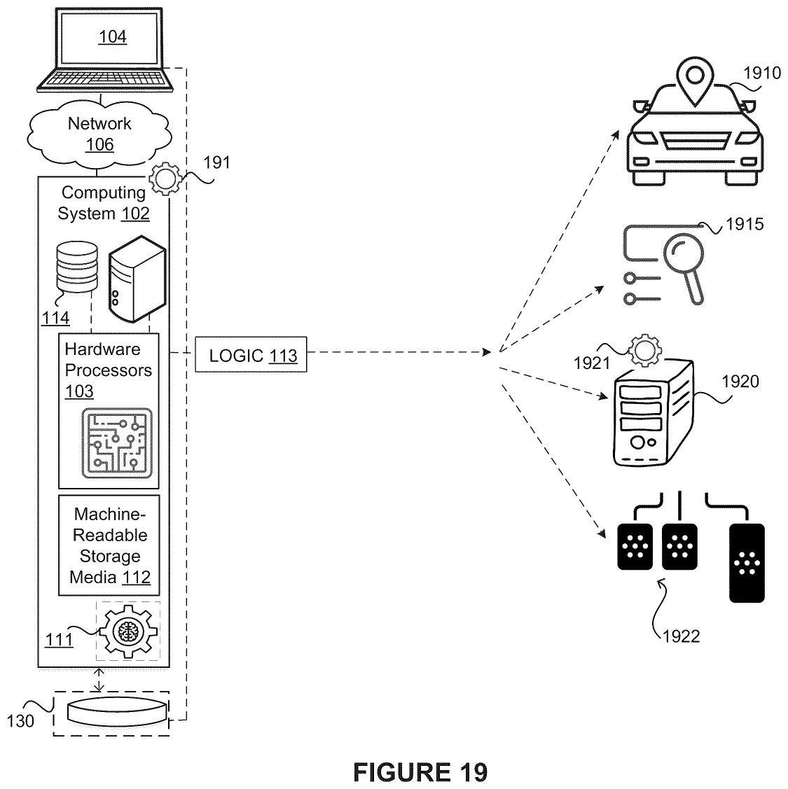

FIG. 19 illustrates that as a result of training the machine learning components 111, certain downstream actions may be triggered, as part of a workflow or a process. Although machine learning components 111 are illustrated in FIG. 19, the foregoing description is also applicable to the machine learning components 161. Therefore, these actions may be in response to generating of seed scenarios and/or generating of additional scenarios. The computing system 102, 152, and/or a different computing system may implement a testing simulation based on the seed scenario and the one or more additional scenarios. The testing simulation includes executing of a test driving operation involving a test vehicle based on the seed scenario and monitoring one or more statistics and test vehicle attributes of the test vehicle. The statistics may include, for a seed scenario or additional scenario, monitoring crash rate distributions, crash type distributions, severity distributions, post-encroachment time distributions, and/or near-miss distributions. In some examples, the test vehicle may include, or be, an ego vehicle.

Specifically, the testing simulation may include performing navigation 1910, additional monitoring 1915, transmitting and/or writing information to a different computing system 1920, for example, via an API 1921, and/or maintenance or other physical operations 1922 such as adjusting a physical or electronic infrastructure of a vehicle in order to better react to certain safety conditions. These operations may be part of a process of conducting simulations using the seed scenario and/or the additional scenarios.

As an example of the additional monitoring 1915, during a simulation using a seed scenario and/or an additional scenario, the computing system 102 and/or a different computing system may monitor the aforementioned statistics and vehicle parameters such as engine operation parameters (e.g., engine rotation rate), moment of inertia, and/or position of center of gravity, to ensure safe operation of a vehicle, in particular, to verify whether attributes or parameters of a vehicle fall within certain operating ranges or thresholds. In some examples, the additional monitoring 1915 may occur in response to certain attributes or parameters falling outside of certain operating ranges or thresholds. This monitoring or recording of other entity types may be performed by the computing system 102, or may be delegated to a different processor. In other examples, a downstream action may include the writing of information 1920. Such writing of information may encompass transmission or presentation of information, an alert, and/or a notification to the computing device 104 and/or to other devices. The information may include indications of which attributes or parameters of a vehicle may fall outside of operating ranges or thresholds, or reasons that an alert was triggered, and/or one or more timestamps corresponding to an originating or creation time of underlying data that caused the triggering of the alert. Alternatively, an alert may be triggered using a predicted time at which an attribute or parameter may be predicted to fall outside of an operating range or threshold.

In yet other examples, a downstream action may entail an applications programming interface (API) 191 of the computing system 102 interfacing with or calling the API 1921 of the different computing system 1920. For example, the different computing system 1920 may perform analysis and/or transformation or modification of data, through some electronic or physical operation. Meanwhile, the physical operations 1922 may include controlling braking, steering, and/or throttle components to effectuate a throttle response, a braking action, and/or a steering action during navigation.

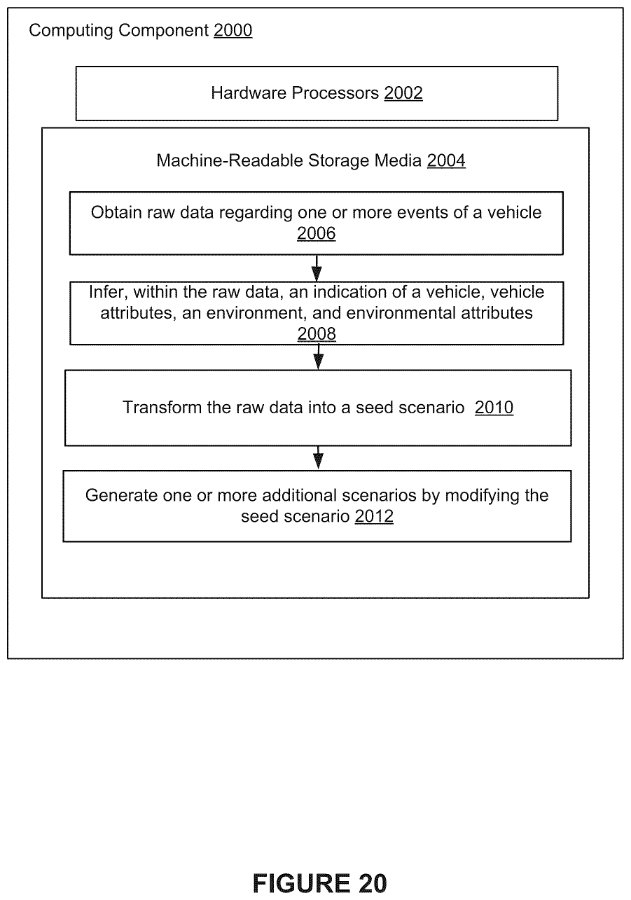

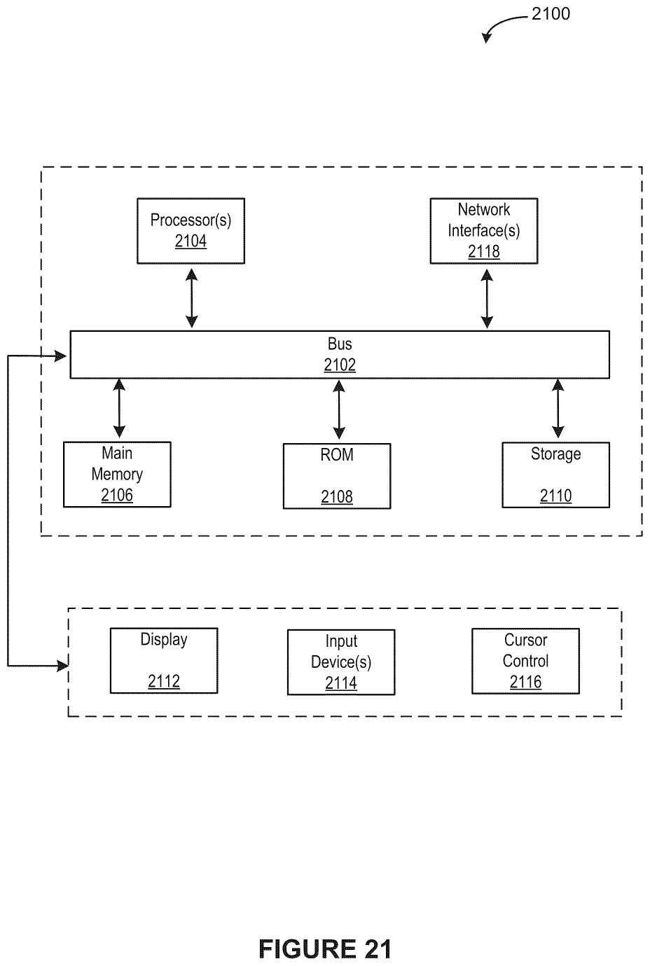

FIG. 20 illustrates a computing component 2000 that includes one or more hardware or other processors 2002 and machine-readable storage media 2004 storing a set of machine-readable/machine-executable instructions that, when executed, cause the processor(s) 2002 to perform an illustrative method of monitoring and/or initiating of downstream actions. The computing component 2000 may be implemented as the computing system 102 of FIG. 1. The processors 1802 may be implemented as the processors 103 and/or the processors 153 of FIGS. 1-16. The machine-readable storage media 2004 may be implemented as the machine-readable storage media 112 of FIG. 1, and may include suitable machine-readable storage media described in FIG. 21.

At step 2006, the processor(s) 2002 may execute machine-readable/machine-executable instructions stored in the machine-readable storage media 2004 to obtain raw data (e.g., the raw data 121 and/or the source data 122 of FIG. 1, and/or other non-textual raw data as illustrated in FIGS. 1-16) regarding one or more events of a vehicle. The obtaining of the raw data may include generating a prompt to extract data from one or more external data sources. In some examples, the raw data 121 and/or the source data 122 may be obtained using a crawler (e.g., the crawler 128) and/or through an API (e.g., the API 129). For example, the processor(s) 2002 may implement an API call via a wrapper or interface. The processor(s) 2002 may output or generate a queue encompassing the corpus of data to be processed following extracting of the data.

At step 2008, the processor(s) 2002 may execute machine-readable/machine-executable instructions stored in the machine-readable storage media 2004 to infer, within the raw data, an indication of a vehicle, vehicle attributes, an environment, and environmental attributes. The inferring may be according to an ontological framework, as described with respect to FIG. 1. The ontological framework defines linkages or relationships among the vehicle and the vehicle attributes, and relationships among the vehicle and other objects within the environment. In some examples, a training process, as described in FIGS. 17-18, in particular, in FIG. 17, may result in modifying of the ontological framework. For example, if the processor(s) 2002 are mistakenly inferring certain attributes or relationships, the ontological framework may be modified to reduce or eliminate such inference.

At step 2010, the processor(s) 2002 may execute machine-readable/machine-executable instructions stored in the machine-readable storage media 2004 to transform the raw data into a seed scenario (e.g., the seed scenario 131 of FIG. 1) according to the ontological framework. The seed scenario may include a file, and a description or a depiction of the vehicle, the vehicle attributes, the environment, and the environmental attributes.

At step 2012, the processor(s) 2002 may generate one or more additional scenarios by modifying the seed scenario. The modifying of the seed scenario is based on modifications to the environmental attributes, the vehicle attributes, and navigation attributes, as illustrated in FIG. 16. The seed scenario and/or the additional scenarios may be used to implement simulations and/or downstream actions, such as those illustrated in FIG. 19.

The techniques described herein, for example, are implemented by one or more special-purpose computing devices. The special-purpose computing devices may be hard-wired to perform the techniques, or may include circuitry or digital electronic devices such as one or more application-specific integrated circuits (ASICs) or field programmable gate arrays (FPGAs) that are persistently programmed to perform the techniques, or may include one or more hardware processors programmed to perform the techniques pursuant to program instructions in firmware, memory, other storage, or a combination.

FIG. 21 illustrates a block diagram of a computer system 2100 upon which any of the embodiments described herein may be implemented. The computer system 2100 includes a bus 2102 or other communication mechanism for communicating information, one or more hardware or other processors, such as cloud processors, 2104 coupled with bus 2102 for processing information. A description that a device performs a task is intended to mean that one or more of the processor(s) 2104 performs.

The computer system 2100 also includes a main memory 2106, such as a random access memory (RAM), cache and/or other dynamic storage devices, coupled to bus 2102 for storing information and instructions to be executed by processor 2104. Main memory 2106 also may be used for storing temporary variables or other intermediate information during execution of instructions to be executed by processor 2104. Such instructions, when stored in storage media accessible to processor 2104, render computer system 2100 into a special-purpose machine that is customized to perform the operations specified in the instructions.

The computer system 2100 further includes a read only memory (ROM) 2108 or other static storage device coupled to bus 2102 for storing static information and instructions for processor 2104. A storage device 2110, such as a magnetic disk, optical disk, or USB thumb drive (Flash drive), etc., is provided and coupled to bus 2102 for storing information and instructions.

The computer system 2100 may be coupled via bus 2102 to output device(s) 2112, such as a cathode ray tube (CRT) or LCD display (or touch screen), for displaying information to a computer user. Input device(s) 2114, including alphanumeric and other keys, are coupled to bus 2102 for communicating information and command selections to processor 2104. Another type of user input device is cursor control 2116. The computer system 2100 also includes a communication interface 2118 coupled to bus 2102.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise. The phrases “at least one of,” “at least one selected from the group of,” or “at least one selected from the group consisting of,” and the like are to be interpreted in the disjunctive (e.g., not to be interpreted as at least one of A and at least one of B).

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiment.

A component being implemented as another component may be construed as the component being operated in a same or similar manner as the another component, and/or comprising same or similar features, characteristics, and parameters as the another component.

1. A system comprising:
one or more processors; and
a memory storing instructions that, when executed by the one or more processors, cause the system to perform:
obtaining raw data associated with one or more events of a vehicle;
inferring, within the raw data, an attribute of the vehicle according to an ontological framework, wherein the ontological framework defines at least one relationship associated with the vehicle;
transforming the raw data into a seed scenario according to the ontological framework, wherein the seed scenario comprises at least one file, and the seed scenario comprises a description or a depiction of the vehicle; and
generating one or more additional scenarios based on one or more modifications to the seed scenario.

2. The system of claim 1, wherein the obtaining of the raw data and the transforming of the raw data are performed in association with a large language model (LLM).

3. The system of claim 2, wherein the LLM is trained iteratively, based on a first training dataset that comprises compiled examples of correctly generated seed scenarios and previously known or obtained incorrectly generated seed scenarios before the transforming of the raw data into the seed scenario, and a second training dataset that comprises incorrectly generated scenarios during the transforming of the raw data.

4. The system of claim 3, wherein the iterative training comprises training the LLM over two stages, wherein a first stage is based on the first training dataset prior to the transforming of the raw data into the seed scenario and a second stage is based on the second training dataset following the transforming of the raw data into the seed scenario.

5. The system of claim 1, wherein the obtaining of the raw data comprises receiving any updates of new raw data from an external data source via an applications programming interface (API); and generating a queue to process the any updates.

6. The system of claim 1, wherein the raw data comprises structured data and unstructured data, and the transforming of the raw data comprises recognizing one or more additional attributes of the vehicle or of other objects from the unstructured data that are absent or undetected from the structured data and integrating the one or more additional attributes into the seed scenario.

7. The system of claim 1, wherein the obtaining of the raw data comprises obtaining the raw data from different data sources, and the transforming of the raw data comprises resolving any discrepancies within the different data sources.

8. The system of claim 1, wherein the raw data comprises textual data and media data, and the transforming of the raw data comprises recognizing one or more additional attributes of the vehicle or of the other objects from the media data that are absent or undetected from the textual data and integrating the one or more additional attributes into the seed scenario.

9. The system of claim 1, wherein the one or more events comprise an accident or a disengagement.

10. The system of claim 1, wherein the instructions further cause the system to perform:
implementing a testing simulation based on the seed scenario and the one or more additional scenarios, wherein the testing simulation comprises executing of a test driving operation involving a test vehicle based on the seed scenario and monitoring one or more test vehicle attributes of the test vehicle.

11. A method comprising:
obtaining raw data associated with one or more events of a vehicle;
inferring, within the raw data, an attribute of the vehicle according to an ontological framework, wherein the ontological framework defines at least one relationship associated with the vehicle;
transforming the raw data into a seed scenario according to the ontological framework, wherein the seed scenario comprises at least one file, and the seed scenario comprises a description or a depiction of the vehicle; and
generating one or more additional scenarios based on one or more modifications to the seed scenario.

12. The method of claim 11, wherein the obtaining of the raw data and the transforming of the raw data are performed in association with a large language model (LLM).

13. The method of claim 12, wherein the LLM is trained iteratively, based on a first training dataset that comprises compiled examples of correctly generated seed scenarios and previously known or obtained incorrectly generated seed scenarios before the transforming of the raw data into the seed scenario, and a second training dataset that comprises incorrectly generated scenarios during the transforming of the raw data.

14. The method of claim 13, wherein the iterative training comprises training the LLM over two stages, wherein a first stage is based on the first training dataset prior to the transforming of the raw data into the seed scenario and a second stage is based on the second training dataset following the transforming of the raw data into the seed scenario.

15. The method of claim 11, wherein the obtaining of the raw data comprises receiving any updates of new raw data from an external data source via an applications programming interface (API); and generating a queue to process the any updates.

16. The method of claim 11, wherein the raw data comprises structured data and unstructured data, and the transforming of the raw data comprises recognizing one or more additional attributes of the vehicle or of the other objects from the unstructured data that are absent or undetected from the structured data and integrating the one or more additional attributes into the seed scenario.

17. The method of claim 11, wherein the obtaining of the raw data comprises obtaining the raw data from different data sources, and the transforming of the raw data comprises resolving any discrepancies within the different data sources.

18. The method of claim 11, wherein the raw data comprises textual data and media data, and the transforming of the raw data comprises recognizing one or more additional attributes of the vehicle or of the other objects from the media data that are absent or undetected from the textual data and integrating the one or more additional attributes into the seed scenario.

19. The method of claim 11, wherein the one or more events comprise an accident or a disengagement.

20. The method of claim 11, further comprising:
implementing a testing simulation based on the seed scenario and the one or more additional scenarios, wherein the testing simulation comprises executing of a test driving operation involving a test vehicle based on the seed scenario and monitoring one or more test vehicle attributes of the test vehicle.
